(19) United States
(12) Patent Application Publication
(10) Pub. No.: US 2024/0279788 A1
(43) Pub. Date: Aug. 22, 2024

(54) MASK ASSEMBLY AND MANUFACTURING METHOD THEREOF

(71) Applicant: Samsung Display Co., Ltd., Yongin-si (KR)

(72) Inventors: JONGDAE LEE, Yongin-si (KR); WONYOUNG JANG, Yongin-si (KR)

(73) Assignee: Samsung Display Co., Ltd., Yongin-si (KR)

(21) Appl. No.: 18/646,003

(22) Filed: Apr. 25, 2024

Related U.S. Application Data
(63) Continuation-in-part of application No. 18/449,822, filed on Aug. 15, 2023.

(30) Foreign Application Priority Data
Oct. 20, 2022 (KR) 10-2022-0135639

(51) Int. Cl. C23C 14/04; C23C 16/04

(52) U.S. Cl. CPC C23C 14/042; C23C 16/042

(57) ABSTRACT

A mask assembly includes a frame opening, and a mask sheet. The mask sheet includes a first mask including a first body part having at least one first deposition opening, first coupling portions, each of which protrudes from at least one first side of the first body part, and a second mask including a second body part having at least one second deposition opening, second coupling portions, each of which protrudes from at least one first side of the second body part, The at least one first side of the first mask and the at least one first side of the second mask face each other. The first coupling portions overlap the second coupling portions, respectively.

### CROSS-REFERENCE TO RELATED APPLICATION(S)

This is a continuation-in-part application of U.S. Patent Application No. 18/449,822, filed Aug. 15, 2023 (now pending), the disclosure of which is incorporated herein by reference in its entirety. U.S. patent application Ser. No. 18/449,822 claims priority to and benefits of Korean Patent Application No. 10-2022-0135639 under 35 U.S.C. § 119, filed on Oct. 20, 2022 in the Korean Intellectual Property Office (KIPO), the entire contents of which are incorporated herein by reference.

### BACKGROUND

### 1. Technical Field

The disclosure relates to a mask assembly that forms a common layer of a display panel, and a method for manufacturing the mask assembly.

### 2. Description of the Related Art

A display panel includes multiple pixels. The pixels may each include a driving element such as a transistor, and a display element such as an organic light emitting element. The display element may be formed by stacking an electrode and various functional layers on a substrate.

The functional layers constituting the display element may be patterned and provided using a mask having an open region defined to pass through the functional layers. Here, the shape of each of the patterned functional layers may be controlled according to the shape, etc., of the open region of the mask. Accordingly, there is a need for the technical development of a mask assembly in which the open region is processed to have high precision to improve deposition quality of the patterned functional layers, and a method for manufacturing such a mask assembly.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a mask assembly that forms a common layer of a display panel having a large area.

The disclosure also provides a mask assembly manufacturing method that improves quality of a mask assembly.

An embodiment provides a mask assembly that may include a frame extending in a first direction and a second direction intersecting each other, the frame including a frame opening, and a mask sheet coupled to the frame. The mask sheet may include a first mask that includes a first body part having at least one first deposition opening corresponding to the frame opening, and first coupling portions, each of which protrudes from at least one first side of the first body part, which overlaps the frame opening, and a second mask that includes a second body part having at least one second deposition opening corresponding to the frame opening, and second coupling portions, each of which protrudes from at least one first side of the second body part, which overlaps the frame opening. The at least one first side of the first mask and the at least one first side of the second mask may face each other in the frame opening. The first coupling portions may overlap the second coupling portions, respectively.

In an embodiment, a thickness of each of the first coupling portions may be less than a thickness of the first body part, a thickness of each of the second coupling portions may be less than a thickness of the second body part, and a sum of respective thicknesses of one of the first coupling portions and one of the second coupling portions, which overlap each other, may be equal to at least one of the thickness of the first body part and the thickness of the second body part.

In an embodiment, the first coupling portions may each be in contact with the at least one first side of the second body part, and the second coupling portions may each be in contact with the at least one first side of the first body part.

In an embodiment, the at least one first side of the first body part and the at least one first side of the second body part may extend in the first direction. The first coupling portions may each have a width in the first direction, which increases from an end adjacent to the at least one first side of the second body part toward the at least one first side of the first body part, and the second coupling portions may each have a width in the first direction, which increases from an end adjacent to the at least one first side of the first body part toward the at least one first side of the second body part.

In an embodiment, the first coupling portions may include first sub-coupling portions, which protrude from the at least one first side of the first body part at a first height in a thickness direction of the first body part, and second sub-coupling portions which protrude from the at least one first side of the first body part at a second height different from the first height in the thickness direction and are disposed alternately with the first sub-coupling portions. The second coupling portions may include first sub-coupling portions, which protrude from the at least one first side of the second body part at the second height in the thickness direction, and second sub-coupling portions which protrude from the at least one first side of the second body part at the first height in the thickness direction and are disposed alternately with the first sub-coupling portions. The first sub-coupling portions of the first coupling portion may overlap the first sub-coupling portions of the second coupling portions, respectively, and the second sub-coupling portions of the first coupling portion may overlap the second sub-coupling portions of the second coupling portion, respectively.

In an embodiment, the first mask may further include first tension portions which protrude from at least one second side of the first body part, and each of which may have at least a portion overlapping the frame. The second mask may further include second tension portions which protrude from at least one second side of the second body part, and each of which may have at least a portion overlapping the frame.

In an embodiment, the first tension portions and the first coupling portions may not overlap the at least one first deposition opening, and the second tension portions and the second coupling portions may not overlap the at least one second deposition opening, when viewed in the first direction and the second direction.

In an embodiment, the first mask may further comprise first sub-tension portions which protrude from the at least one second side of the first body part, each of which is disposed between two of the first tension portions, and the second mask may further comprise second sub-tension portions which protrude from the at least one second side of the second body part, each of which is disposed between two of the second tension portions.

In an embodiment, the frame, the first mask, and the second mask may each include at least one of invar and stainless steel.

In an embodiment, the at least one first deposition opening may include a plurality of first deposition openings, the at least one second deposition opening may include a plurality of second deposition openings, and the plurality of first deposition openings may be disposed in the same shape as the plurality of second deposition openings.

In an embodiment, the plurality of first deposition openings may be disposed apart from each other in the first direction.

In an embodiment, the plurality of first deposition openings may be provided in n rows×m columns n and m being natural numbers, and the plurality of first deposition openings may be disposed apart from each other in the first direction and the second direction.

In an embodiment, the at least one first deposition opening may include a plurality of first deposition openings, the at least one second deposition opening may include a plurality of second deposition openings, and the plurality of first deposition openings may be disposed in a different shape from the plurality of second deposition openings.

In an embodiment, a coupling region overlapping one of the first coupling portions and one of second coupling portions, which overlap each other, may have a width of about 500 μm to about 5 mm in the first direction.

In an embodiment, the first mask may further include first sub-tension portions, each of which protrudes from the at least one first side of the first body part and is disposed between two of the first coupling portions. The second mask may further include second sub-tension portions, each which protrudes from the at least one first side of the second body part and is disposed between two of the second coupling portions. The first sub-coupling portions may overlap the second sub-coupling portions, respectively.

In an embodiment, a curve may be defined between two adjacent first tension portions among the first tension portions in a plan view, and a curve may be defined between two adjacent second tension portions among the second tension portions in a plan view.

In an embodiment, a method for manufacturing a mask assembly includes disposing, on a frame, a first mask that includes a first body part having at least one first deposition opening, first tension portions protruding from the first body part, and first coupling portions protruding from the first body part, disposing, on the frame, a second mask that includes a second body part having at least one second deposition opening, second tension portions protruding from the second body part, and second coupling portions protruding from the second body part, aligning the first coupling portions with the second coupling portions, coupling the aligned first coupling portions and second coupling portions to form a mask sheet, tensioning the first tension portions and the second tension portions, and coupling the tensioned mask sheet to the frame.

In an embodiment, the first coupling portions and second coupling portions may be coupled to each other by welding, and the mask sheet and the frame may be coupled to each other by welding.

In an embodiment, the frame may have a rectangular shape extending in a first direction and a second direction intersecting each other. Some of the first tension portions may protrude in the second direction from an upper side and a lower side of the first body part, which extend in the first direction, and others of the first tension portions may protrude in the first direction from a side of the first body part, which extends in the second direction. Some of the second tension portions may protrude in the second direction from an upper side and a lower side of the second body part, which extend in the first direction, and others of the second tension portions may protrude in the first direction from a side of the second body part, which extends in the second direction. In the tensioning of the first and second tension portions, the first and second tension portions may be tensioned in protruding directions.

In an embodiment, the mask assembly manufacturing method may further include removing at least a portion of each of the first tension portions and the second tension portions.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1 is a schematic cross-sectional view of a deposition device according to an embodiment;

FIG. 2A is a schematic plan view of a mask assembly according to an embodiment.

FIG. 2B is an exploded schematic perspective view of a mask assembly according to an embodiment;

FIG. 3A and FIG. 3B are schematic plan views of mask assemblies according to embodiments;

FIG. 4 is a schematic exploded perspective view of a mask assembly according to an embodiment;

FIG. 5 is a schematic plan view of a mask assembly according to an embodiment;

FIG. 6 is a schematic cross-sectional view of a display panel according to an embodiment;

FIG. 7 is a schematic plan view of a mask assembly according to an embodiment;

FIG. 8 is a schematic plan view of a mask assembly according to an embodiment;

FIG. 9 is a schematic cross-sectional view taken along line II-II' in FIG. 8;

FIG. 10 is an exploded schematic plan view of a portion of a mask sheet according to an embodiment;

FIG. 11A is a schematic plan view of a mask assembly according to an embodiment;

FIG. 11B is a schematic perspective view illustrating masks according to an embodiment;

FIG. 12A is a schematic perspective view illustrating masks according to an embodiment;

FIG. 12B is an exploded schematic perspective view of a portion of masks according to an embodiment;

FIG. 12C is a schematic plan view of a mask according to an embodiment;

FIG. 12D is a schematic plan view of a mask according to an embodiment;

FIG. 12E is a perspective view illustrating masks according to an embodiment of the inventive concept;

FIG. 12F is a perspective view illustrating masks according to an embodiment of the inventive concept;

FIG. 12G is a perspective view illustrating masks according to an embodiment of the inventive concept;

FIG. 13A is a schematic perspective view illustrating a mask assembly manufacturing method according to an embodiment;

FIG. 13B is a schematic perspective view illustrating a mask assembly manufacturing method according to an embodiment;

FIG. 13C is a schematic perspective view illustrating a mask assembly manufacturing method according to an embodiment;

FIG. 13D is a schematic perspective view illustrating a mask assembly manufacturing method according to an embodiment; and

FIG. 13E is a schematic plan view illustrating a mask assembly manufacturing method according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

It will be understood that when an element (or region, layer, section, etc.) is referred to as being “on”, “connected to” or “coupled to” another element, it can be disposed directly on, connected or coupled to the other element or a third intervening element may be disposed between the elements.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms “first,”“second,” etc. may be used herein to describe various elements, these elements should not be limited by these terms. These terms are only used to distinguish one element from another element. For example, a first element could be termed a second element without departing from the teachings of the disclosure, and similarly, a second element could be termed a first element. As used herein, the singular forms are intended to include the plural forms as well, unless the context clearly indicates otherwise.

In addition, terms such as “below”, “beneath”, “on” and “above”, are used for explaining the relation of elements shown in the drawings. The terms are relative concepts and are explained based on the direction shown in the drawing.

The terms “comprises,”“comprising,”“includes,” and/or “including,”“has,”“have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined or implied, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

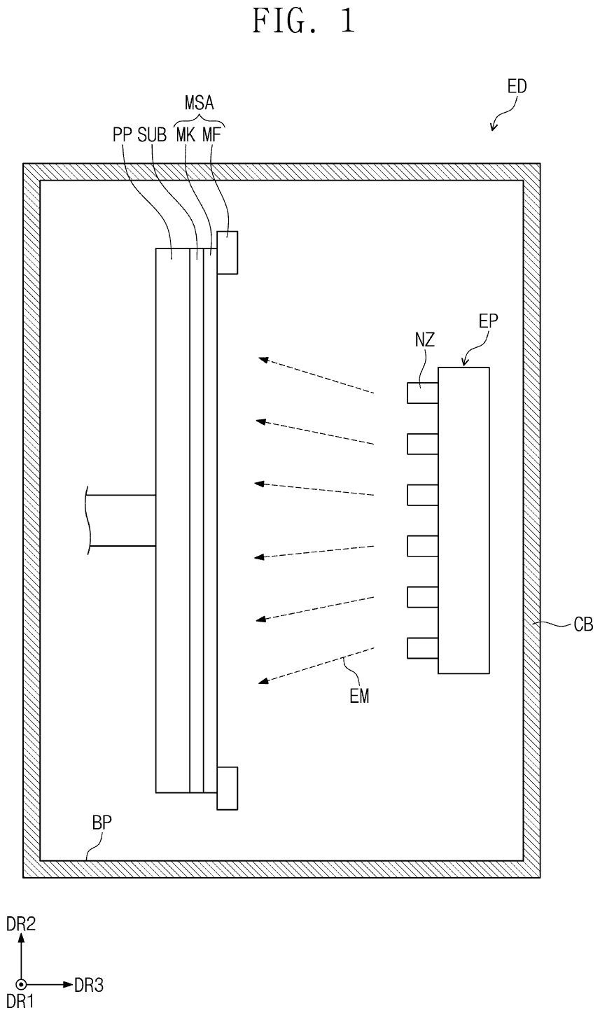

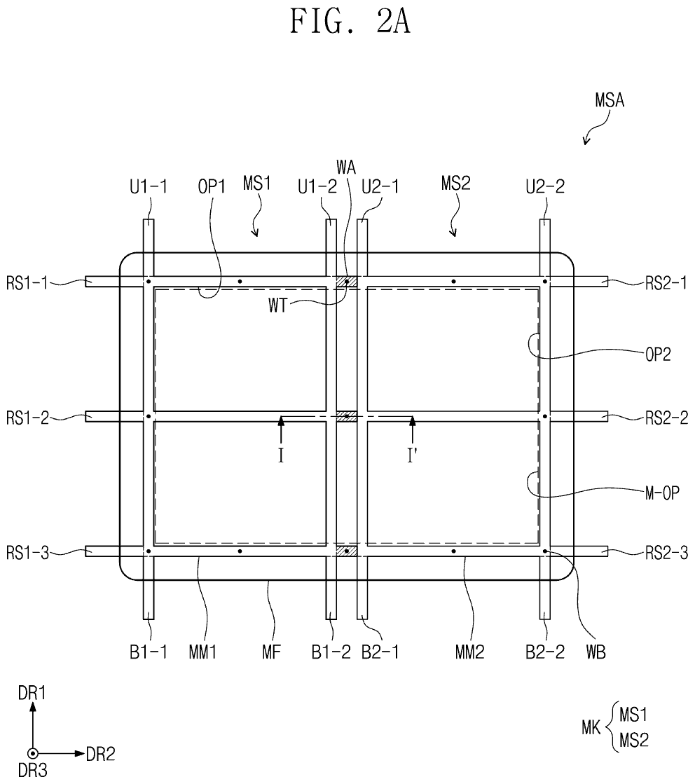

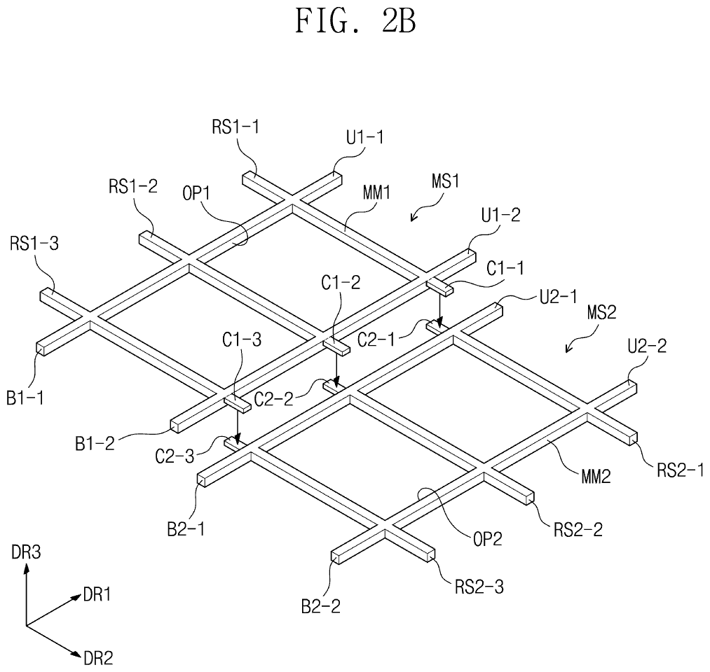

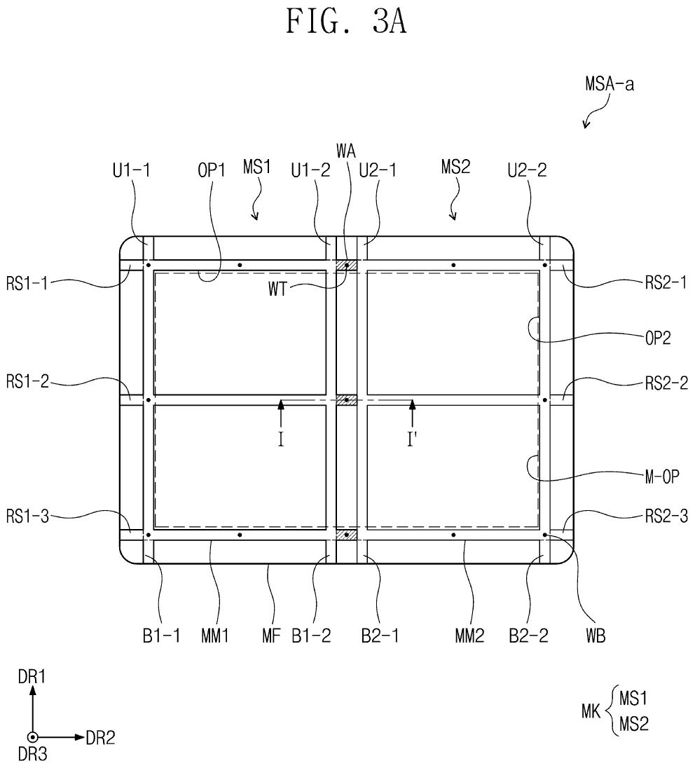

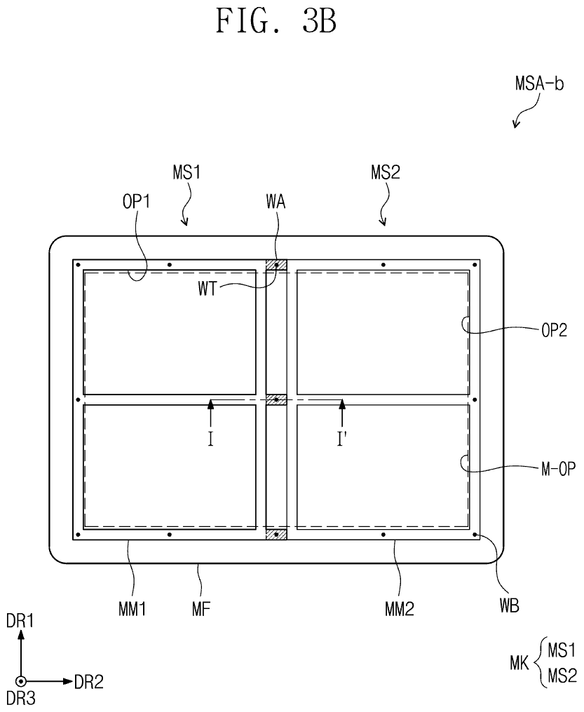

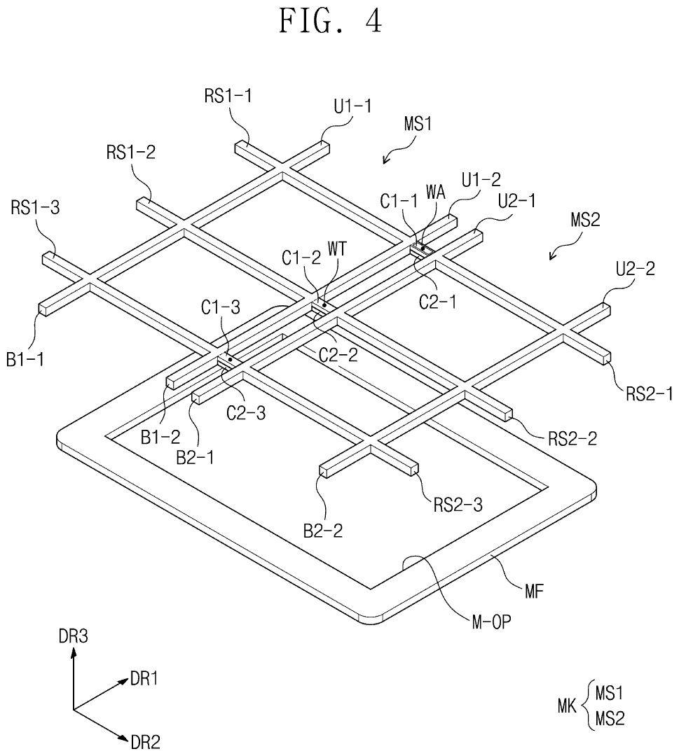

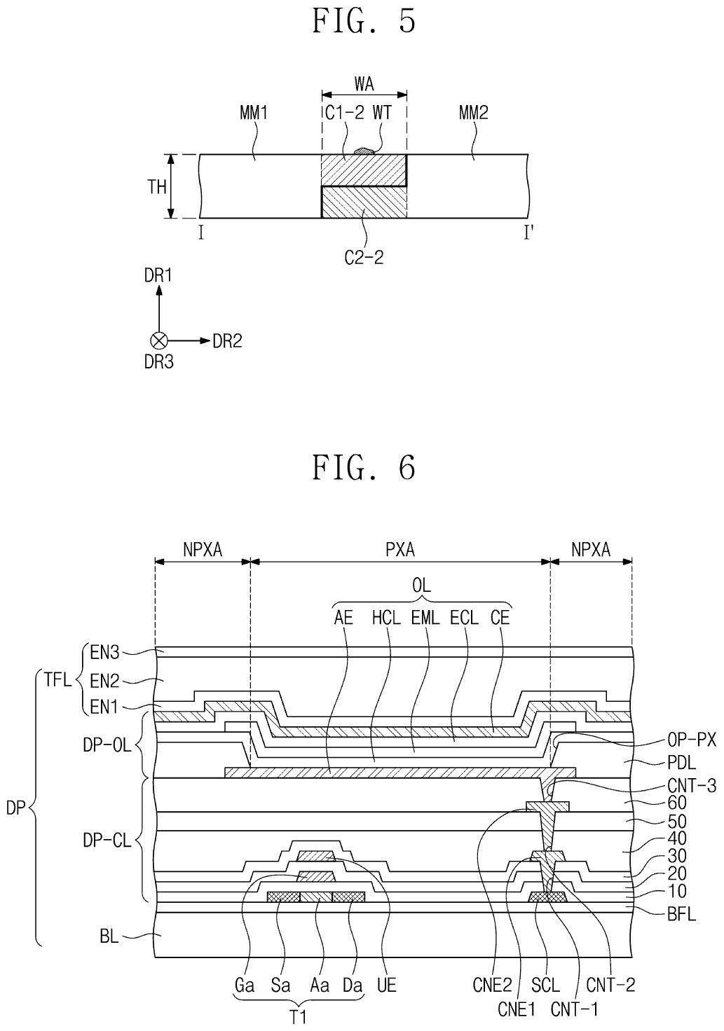

FIG. 1 is a schematic cross-sectional view of a deposition device according to an embodiment. FIG. 2A is a schematic plan view of a mask assembly according to an embodiment. FIG. 2B is an exploded schematic perspective view of a mask assembly according to an embodiment. FIG. 3A and FIG. 3B are schematic plan views of mask assemblies according to embodiments. FIG. 4 is a schematic exploded perspective view of a mask assembly according to an embodiment. FIG. 5 is a schematic cross-sectional view taken along line I-I′ in FIG. 3A.

Referring to FIG. 1, a deposition device ED according to an embodiment may include a chamber CB, a deposition member EP, a fixing member PP, and a mask assembly MSA. The mask assembly MSA may include a mask sheet MK, in which masks are coupled to each other, and a frame MF. The deposition device ED according to an embodiment may further include an additional mechanical device for realizing an in-line system.

The chamber CB may provide an inner space in which a depositing process may be performed on a substrate SUB. The deposition member EP, the fixing member PP, and the mask assembly MSA may be disposed in the inner space of the chamber CB. The chamber CB may define a sealed space, and may set a deposition condition to a vacuum. The chamber CB may include at least one gate, and the chamber CB may be opened and closed through the gate. A mask MK, a mask frame MF, and the substrate SUB may enter and exit the chamber CB through the gate provided in the chamber CB.

The chamber CB may include a bottom surface BP, a ceiling surface facing the bottom surface BP in a second direction DR2, and multiple side walls that connect the bottom surface BP and the ceiling surface to each other. The bottom surface BP, the ceiling surface, and the side walls may constitute the chamber CB having a hexahedral shape. The bottom surface BP of the chamber CB may be parallel to a plane defined by a first direction DR1 and a third direction DR3, and a normal direction to the bottom surface of the chamber CB may be parallel to the second direction DR2. In the disclosure, the expression “in a plan view” may mean on a plane parallel to a plane defined by two directions (for example, the first direction DR1 and the second direction DR2).

The fixing member PP may be disposed inside the deposition chamber CB and face the deposition member EP in the third direction DR3. The fixing member PP may fix the substrate SUB to the mask assembly MSA. The fixing member PP may include a jig or a robot arm that holds the mask MK. The fixing member PP may include magnetic substances for allowing the mask MK and the substrate SUB to be in close contact with each other. For example, the magnetic substances may generate a magnetic force to fix the mask MK, and the substrate SUB disposed between the mask MK and the fixing member PP may be in close contact with the mask MK.

The substrate SUB may be a workpiece on which a deposition material is deposited. The substrate SUB may include a support substrate and a synthetic resin layer disposed on the support substrate. The support substrate may be removed in the second half of a display panel manufacturing process, and the synthetic resin layer may correspond to a base layer BL in FIG. 1. According to components formed through the depositing process, the substrate SUB may include some components of a display panel DP formed on the base layer BL.

The deposition member EP may be disposed to face the fixing member PP inside the deposition chamber CB in the second direction DR2. The deposition member EP may include a space, in which the deposition material EM is accommodated, and at least one nozzle NZ. The deposition material EM may include an inorganic material, a metal, or an organic material, which can be sublimated or vaporized. For example, the deposition material EM may include an organic material for forming functional layers included in a display panel DP (see FIG. 6). However, the deposition material EM is not limited to the foregoing examples. The deposition material EM sublimated or vaporized may be sprayed toward the substrate SUB through the nozzle NZ. The deposition material EM may pass through the mask assembly MSA so as to be deposited on the substrate SUB.

Although it is illustrated that the deposition device ED according to an embodiment performs the depositing process on the substrate SUB arranged (disposed) in a vertical type on a cross-sectional view, the depositing process is not limited thereto and may be performed in a state in which the substrate SUB is arranged in a horizontal type. Here, the deposition material EM may pass through the mask assembly MSA and be deposited on the substrate SUB.

The deposition device ED according to an embodiment may further include a stage for preventing the mask assembly MSA having a large area from sagging by gravity. The stage may be fixed to at least one side wall of the side walls of the chamber CB and support the mask assembly MSA.

In an embodiment, the deposition device ED according to an embodiment may further include a heat dissipating plate disposed between the mask assembly MSA and the deposition member EP. The heat dissipating plate may include a material having high thermal conductivity. For example, the heat dissipating plate may include a metal such as aluminum or copper, an alloy thereof, carbon, graphite, or the like. The heat dissipating plate may absorb heat dissipated from the deposition member EP so as to prevent the mask assembly MSA from being deformed by the heat during the depositing process.

Referring to FIGS. 2A to 4, the mask assembly MSA may include the mask sheet MK and the frame MF. In the disclosure, the mask sheet MK may be defined, for example, as a state in which multiple masks MS1 and MS2 are coupled to each other by welding.

The frame MF according to an embodiment may include a frame opening M-OP. The deposition material EM (see FIG. 1) sprayed from the deposition member EP (see FIG. 1) may be provided for the mask sheet MK through the frame opening M-OP. The mask sheet MK and the frame MF may each include at least one of invar and stainless steel.

First and second masks MS1 and MS2 may be disposed on the frame MF. The first mask MS1 may include a first body part MM1, multiple first tension portions U1-1, U1-2, B1-1, B1-2, RS1-1, RS1-2 and RS1-3, and multiple first coupling portions C1-1, C1-2 and C1-3. The first body part MM1, the first tension portions U1-1, U1-2, B1-1, B1-2, RS1-1, RS1-2 and RS1-3, and the first coupling portions C1-1, C1-2 and C1-3 may be provided as a substantially integral structure, but will be separately described for convenience of explanation.

The first body part MM1 may include at least one first opening OP1 corresponding to the frame opening M-OP. The first opening OP1 may be provided in plurality. FIG. 2A illustrates (as an example) that the first body part MM1 includes two first openings OP1 arranged in a matrix shape of 2 rows and 1 column. The first body part MM1 may have at least one first side and at least one second side. The at least one second side may overlap the frame MF, and the at least one first side may include at least a portion that may overlap the frame opening M-OP.

The first tension portions U1-1, U1-2, B1-1, B1-2, RS1-1, RS1-2 and RS1-3 may protrude from multiple of the at least one second side of the first body part MM1. The first tension portions U1-1, U1-2, B1-1, B1-2, RS1-1, RS1-2 and RS1-3 may each be a portion to which a structure for tensioning the first mask MS1 is coupled in coupling of the first mask MS1 to the frame MF.

The first upper tension portions U1-1 and U1-2 may protrude in the first direction DR1 from a second side of the first body part MM1 overlapping an upper side of the frame MF, among the at least one second sides of the first body part MM1, which extend in the second direction DR2.

The first lower tension portions B1-1 and B1-2 may protrude in the first direction DR1 from a second side of the first body part MM1 overlapping a lower side of the frame MF, among the at least one second sides of the first body part MM1, which extend in the second direction DR2. The first-1 upper tension portion U1-1 may be aligned with the first-1 lower tension portion B1-1 in the first direction DR1, and the first-2 upper tension portion U1-2 may be aligned with the first-2 lower tension portion B1-2 in the first direction DR1.

The first lateral tension portions RS1-1, RS1-2 and RS1-3 may protrude in the second direction DR2 from a second side of the first body part MM1, which extends in the first direction DR1. The first lateral tension portions RS1-1, RS1-2 and RS1-3 may be arranged apart from each other in the first direction DR1.

In an embodiment, the first tension portions U1-1, U1-2, B1-1, B1-2, RS1-1, RS1-2 and RS1-3 may not overlap the first openings OP1 when viewed in the first direction DR1 and/or the second direction DR2. Accordingly, even in case that each of the first tension portions U1-1, U1-2, B1-1, B1-2, RS1-1, RS1-2 and RS1-3 is connected to the structure and tensioned in a predetermined or selected direction, the shapes of the first openings OP1 may be maintained.

The second body part MM2 may include at least one second opening OP2 corresponding to the frame opening M-OP. The second opening OP2 may be provided in plurality. FIG. 2A illustrates (as an example) that the second body part MM2 includes two second openings OP2 arranged in a matrix shape of 2 rows and 1 column. According to an embodiment, the arrangement shape of the first openings OP1 included in the first body part MM1 may be the same as the arrangement shape of the second openings OP2 included in the second body part MM2.

The second body part MM2 may have at least one second side “overlapping the frame MF, and at least one first side” of which at least a portion overlaps the frame opening M-OP.

The second tension portions U2-1, U2-2, B2-1, B2-2, RS2-1, RS2-2 and RS2-3 may protrude from the at least one second side of the second body part MM2. The second tension portions U2-1, U2-2, B2-1, B2-2, RS2-1, RS2-2 and RS2-3 may each be a portion to which a structure for tensioning the second mask MS2 is coupled in coupling of the first mask MS2 to the frame MF.

The second upper tension portions U2-1 and U2-2 may protrude in the first direction DR1 from a second side of the second body part MM2 overlapping the upper side of the frame MF, among the at least one second sides of the second body part MM2, which extend in the second direction DR2.

The second lower tension portions B2-1 and B2-2 may protrude in the first direction DR1 from a second side of the second body part MM2 overlapping the lower side of the frame MF, among the at least one second sides of the second body part MM2, which extend in the second direction DR2. The second-1 upper tension portion U2-1 may be aligned with the second-1 lower tension portion B2-1 in the first direction DR1, and the second-2 upper tension portion U2-2 may be aligned with the second-2 lower tension portion B2-2 in the first direction DR1.

The second lateral tension portions RS2-1, RS2-2 and RS2-3 may protrude in the second direction DR2 from at least one second side of the second body part MM2, which extends in the first direction DR1. The second lateral tension portions RS2-1, RS2-2 and RS2-3 may be arranged apart from each other in the first direction DR1.

The first-1 lateral tension portion RS1-1 may be aligned with the second-1 lateral tension portion RS2-1 in the second direction DR2, the first-2 lateral tension portion RS1-2 may be aligned with the second-2 lateral tension portion RS2-3 in the second direction DR2, and the first-3 lateral tension portion RS1-3 may be aligned with the second-3 lateral tension portion RS2-3 in the second direction DR2.

A width of each of the tension portions included in the first mask MS1 and the second mask MS2 described above in a direction crossing the protruding direction of each of the tension portions may be about 15 mm to about 50 mm.

In an embodiment, the second tension portions U2-1, U2-2, B2-1, B2-2, RS2-1, RS2-2 and RS2-3 may not overlap the second openings OP2 when viewed in the first direction DR1 and/or the second direction DR2. Accordingly, even in case that each of the second tension portions U2-1, U2-2, B2-1, B2-2, RS2-1, RS2-2 and RS2-3 is connected to the structure and tensioned in a predetermined or selected direction, the shapes of the second openings OP2 may be maintained.

According to an embodiment, the tension portions of the mask sheet MK, which protrude to the outside of the mask MK, may be removed in the manufacture of the mask assembly MSA.

As illustrated in FIG. 2A and FIG. 2B, the first mask MS1 according to an embodiment may include the first coupling portions C1-1, C1-2 and C1-3. The first coupling portions C1-1, C1-2 and C1-3 may protrude in the second direction DR2 from the first side of the first body part MM1, which overlaps the frame opening M-OP. The first coupling portions C1-1, C1-2 and C1-3 may not overlap the first openings OP1 when viewed in the first direction DR1 and/or the second direction DR2.

The second mask MS2 may include the second coupling portions C2-1, C2-2 and C2-3. The second coupling portions C2-1, C2-2 and C2-3 may protrude in the second direction DR2 from the first side of the second body part MM2, which overlaps the frame opening M-OP. The second coupling portions C2-1, C2-2 and C2-3 may not overlap the second openings OP2 when viewed in the first direction DR1 and/or the second direction DR2.

The first-1 coupling portion C1-1 may overlap the second-1 coupling portion C2-1 in a plan view, the first-2 coupling portion C1-2 may overlap the second-2 coupling portion C2-2 in a plan view, and the first-3 coupling portion C1-3 may overlap the second-3 coupling portion C2-3 in a plan view.

As illustrated in FIG. 3A, the first coupling portions C1-1, C1-2 and C1-3 and the second coupling portions C2-1, C2-2 and C2-3 corresponding thereto may be coupled to each other by welding, and the first mask MS1 and the second mask MS2 coupled to each other may be provided as one mask sheet MK on the frame MF.

In case that the first coupling portions C1-1, C1-2 and C1-3 and the second coupling portions C2-1, C2-2 and C2-3 corresponding thereto are coupled to each other by welding, coupling welding protrusions WT may be formed in coupling regions WA. As used herein, each of regions in which the first coupling portions C1-1, C1-2 and C1-3 and the second coupling portions C2-1, C2-2 and C2-3 corresponding thereto overlap each other may be defined as the “coupling region WA”.

The mask sheet MK may be bonded to the frame MF by welding in a state in which the coupling portions described above are tensioned in the first direction DR1 and/or the second direction DR2. As illustrated in FIG. 3A, in case that the mask sheet MK is coupled to the frame MF by welding, frame welding protrusions WB may be formed. The frame welding protrusions WB may be formed on the first body part MM1 and the second body part MM2 that overlap the frame MF.

As illustrated in FIGS. 4 and 5, in case that the first body part MM1 and the second body part MM2 have the same thickness, a height at which the first coupling portions C1-1, C1-2 and C1-3 protrude from the first body part MM1 and a height at which the second coupling portions C2-1, C2-2 and C2-3 protrude from the second body part MM2 may be different from each other.

For example, the first-2 coupling portion C1-2 may protrude in a direction from the first body part MM1 toward the second body part MM2 at a first height, and the second-2 coupling portion C2-2 may protrude in a direction from the second body part MM2 toward the first body part MM1 at a second height lower than the first height. According to an embodiment, the sum of the thickness of the first-2 coupling portion C1-2 and the thickness of the second-2 coupling portion C2-2 may be less than or equal to a thickness TH of each of the first body part MM1 and the second body part MM2.

According to an embodiment, the first-2 coupling portion C1-2 may have an end in contact with the second body part MM2, and the second-2 coupling portion C2-2 may have an end in contact with the first body part MM1. The first-2 coupling portion C1-2 and the second-2 coupling portion C2-2 may be coupled to each other by welding. The coupling welding protrusion WT may be formed in the coupling region WA. The coupling welding protrusion WT may have a diameter of about 300 μm. The coupling region WA may have a margin width so that at least one coupling welding protrusion WT is formed. Accordingly, the first coupling portions C1-1, C1-2 and C1-3 and the second coupling portions C2-1, C2-2 and C2-3 may each have a width of about 500 μm to about 5 mm in the first direction DR1 and/or the second direction DR2. According to an embodiment, the width of each of the first coupling portions C1-1, C1-2 and C1-3 may be equal to or greater than the width of the first body part MM1, and the width of each of the second coupling portions C2-1, C2-2 and C2-3 may be equal to or greater than the width of the second body part MM2. According to an embodiment, as each of the coupling portions has a width equal to or greater than the width of the corresponding body part, deformation of the body parts may be minimized even in case that the tension portions are tensioned with a predetermined or selected structure. Accordingly, a mask sheet MK with improved quality may be provided.

Referring back to FIG. 3A, a mask assembly MSA-a according to an embodiment may include a mask sheet MK, in which masks MS1 and MS2 are coupled to each other, and a frame MF. The first mask MS1 may include a first body part MM1, multiple first tension portions U1-1, U1-2, B1-1, B1-2, RS1-1, RS1-2 and RS1-3, and multiple first coupling portions C1-1, C1-2 and C1-3. The second mask MS2 may include a second body part MM2, second tension portions U2-1, U2-2, B2-1, B2-2, RS2-1, RS2-2 and RS2-3, and multiple second coupling portions C2-1, C2-2 and C2-3.

Unlike the tension portions described with reference to FIG. 3A, the tension portions according to an embodiment shown in FIG. 3B may be provided in a state in which the first tension portions U1-1, U1-2, B1-1, B1-2, RS1-1, RS1-2 and RS1-3 and the second tension portions U2-1, U2-2, B2-1, B2-2, RS2-1, RS2-2 and RS2-3, which protrude to the outside of the frame MF, are removed. The tension portions may be formed by coupling the masks MS1 and MS2 to the frame MF and removing the first tension portions U1-1, U1-2, B1-1, B1-2, RS1-1, RS1-2 and RS1-3 and the second tension portions U2-1, U2-2, B2-1, B2-2, RS2-1, RS2-2 and RS2-3, which protrude to the outside of the frame MF.

According to an embodiment, grooves, which correspond to the first tension portions U1-1, U1-2, B1-1, B1-2, RS1-1, RS1-2 and RS1-3, the second tension portions U2-1, U2-2, B2-1, B2-2, RS2-1, RS2-2 and RS2-3, the first body part MM1, and the second body part MM2, respectively, may be defined in the frame MF. Thus, the masks MS1 and MS2 may be coupled to the frame MF in a state stably fitted into the grooves of the frame MF.

Referring to FIG. 3B, a mask assembly MSA-b according to an embodiment may include a mask sheet MK, in which masks MS1 and MS2 are coupled to each other, and a frame MF. The first mask MS1 may include a first body part MM1 and multiple first coupling portions C1-1, C1-2 and C1-3. The second mask MS2 may include a second body part MM2 and multiple second coupling portions C2-1, C2-2 and C2-3.

Unlike the mask sheet MK described with reference to FIG. 3A, tension portions protruding from the body parts MM1 and MM2 may be omitted in the mask sheet MK according to this embodiment. The mask sheet MK may be formed by coupling the masks MS1 and MS2 to the frame MF and removing the tension portions protruding from the corresponding body parts MM1 and MM2.

FIG. 6 is a schematic cross-sectional view of a display panel according to an embodiment. Among layers included in a display panel DP described with reference to FIG. 6, some layers may be formed through the depositing process using the mask assembly MSA described with reference to FIGS. 1 to 5. FIG. 6 illustrates, as an example, a cross section of the display panel DP manufactured using the deposition device ED (see FIG. 1).

Referring to FIG. 6, the display panel DP according to an embodiment may be a light emitting display panel. For example, the display panel DP may be an organic light emitting display panel, an inorganic light emitting display panel, or a quantum dot light emitting display panel. A light emitting layer of the organic light emitting display panel may include an organic luminescent material, and a light emitting layer of the inorganic light emitting display panel may include an inorganic luminescent material. A light emitting layer of the quantum dot light emitting display panel may include a quantum dot, a quantum rod, and/or the like. Hereinafter, the display panel DP is described as the organic light emitting display panel (as an example).

The display panel DP may include multiple pixels. Each of the pixels may include at least one transistor and a light emitting element. FIG. 6 illustrates, as an example, a region of the pixel of the display panel DP, in which one transistor T1 and a light emitting element OL are disposed.

Referring to FIG. 6, the display panel DP may include a base layer BL, a circuit element layer DP-CL, a display element layer DP-OL, and an encapsulation layer TFL.

The base layer BL may provide a base surface on which the circuit element layer DP-CL is disposed. The base layer BL may include a synthetic resin layer. The synthetic resin layer may be formed on a work substrate used at an earlier stage of a manufacturing process of the display panel DP and a conductive layer, an insulation layer and so on may be formed on the synthetic resin layer. Thereafter, the work substrate may be removed, and the synthetic resin layer from which the work substrate has been removed may correspond to the base layer BL.

At least one inorganic layer may be disposed on a top surface of the base layer BL. The inorganic layer may include a barrier layer and/or a buffer layer. FIG. 6 illustrates, as an example, a buffer layer BFL disposed on the base layer BL. The buffer layer BFL may improve adhesion between the base layer BL and a semiconductor pattern of the circuit element layer DP-CL.

The circuit element layer DP-CL may be disposed on the buffer layer BFL. The circuit element layer DP-CL may include at least one insulation layer and a circuit element. The circuit element may include signal lines, a driving circuit of a pixel, etc. The circuit element layer DP-CL may be formed using a process of forming the insulation layer, a semiconductor layer, and a conductive layer through coating, deposition and/or the like, and a process of patterning the insulation layer, the semiconductor layer, and the conductive layer by performing a photolithography process.

In an embodiment, the circuit element layer DP-CL may include the transistor T1, a connection signal line SCL, connection electrodes CNE1 and CNE2, and multiple insulation layers 10 to 60. The insulation layers 10 to 60 may include first to sixth insulation layers 10 to 60 that are stacked on each other on the buffer layer BFL. The first to sixth insulation layers 10 to 60 may each include at least one of an inorganic layer and an organic layer.

The transistor T1 may include the semiconductor pattern, which includes a source region Sa, an active region Aa, and a drain region Da, and a gate electrode Ga. The semiconductor pattern of the transistor T1 may include polysilicon. However, the disclosure is not limited thereto, and the semiconductor pattern may include amorphous silicon or a metal oxide.

The semiconductor pattern may be divided into multiple regions according to conductivity. For example, the semiconductor pattern may have different electrical properties according to whether the semiconductor pattern is doped or not or whether the metal oxide is reduced. A region of the semiconductor pattern, which has high conductivity, may serve as an electrode or a signal line, and may correspond to the source region Sa and the drain region Da of the transistor T1. A region which is non-doped or non-reduced to have relatively low conductivity may correspond to the active region Aa (or channel region) of the transistor T1.

The connection signal line SCL may be formed from the semiconductor pattern, and may be disposed on the same layer as the source region Sa, the active region Aa, and the drain region Da of the transistor T1. According to an embodiment, the connection signal line SCL may be electrically connected to the drain region Da of the transistor T1 in a plan view.

The first insulation layer 10 may cover the semiconductor pattern of the circuit element layer DP-CL. The gate electrode Ga may be disposed on the first insulation layer 10. The gate electrode Ga may overlap the active region Aa. The gate electrode Ga may function as a mask in the doping of the semiconductor pattern. An upper electrode UE may be disposed on the second insulation layer 20. The upper electrode UE may overlap the gate electrode Ga.

The first connection electrode CNE1 and the second connection electrode CNE2 may be disposed between the transistor T1 and the light emitting element OL and electrically connect the transistor T1 and the light emitting element OL to each other. The first connection electrode CNE1 may be disposed on the third insulation layer 30 and connected to the connection signal line SCL through a contact hole CNT-1 passing through the first to third insulation layers 10 to 30. The second connection electrode CNE2 may be disposed on the fifth insulation layer 50 and connected to the first connection electrode CNE1 through a contact hole CNT-2 passing through the fourth and fifth insulation layers 40 and 50.

The display element layer DP-OL may be disposed on the circuit element layer DP-CL. The display element layer DP-OL may include the light emitting element OL and a pixel defining film PDL. The light emitting element OL may include a first electrode AE, a hole control layer HCL, a light emitting layer EML, an electron control layer ECL, and a second electrode CE.

The first electrode AE and the pixel defining film PDL may be disposed on the sixth insulation layer 60. The first electrode AE may be connected to the second connection electrode CNE2 through a contact hole CNT-3 passing through the sixth insulation layer 60. A light emitting opening OP-PX which exposes at least a portion of the first electrode AE may be defined in the pixel defining film PDL, and the at least a portion of the first electrode AE, which is exposed by the light emitting opening OP-PX, may correspond to a light emitting region PXA. A non-light emitting region NPXA may surround the light emitting region PXA.

The hole control layer HCL and the electron control layer ECL may be formed, in common, in the light emitting region PXA and the non-light emitting region NPXA. The light emitting layer EML may be provided in a pattern shape so as to correspond to the light emitting opening OP-PX.

The hole control layer HCL and the electron control layer ECL, each of which has a film shape, may be deposited using a different method from the light emitting layer EML. The hole control layer HCL and the electron control layer ECL may be formed, in common, in the pixels using the mask assembly MSA according to an embodiment.

The encapsulation layer TFL may include multiple thin films. The encapsulation layer TFL according to an embodiment may include first to third thin films EN1, EN2 and EN3 that are stacked on each other. The first to third thin films EN1, EN2 and EN3 may each include at least one of an inorganic film and an organic film. The inorganic film may prevent the light emitting element OL from moisture and/or oxygen. The organic film may prevent the light emitting element OL from foreign matters such as dust. However, the configuration of the encapsulation layer TFL is not limited to that illustrated as long as the encapsulation layer TFL may protect the light emitting element OL or improve emission efficiency.

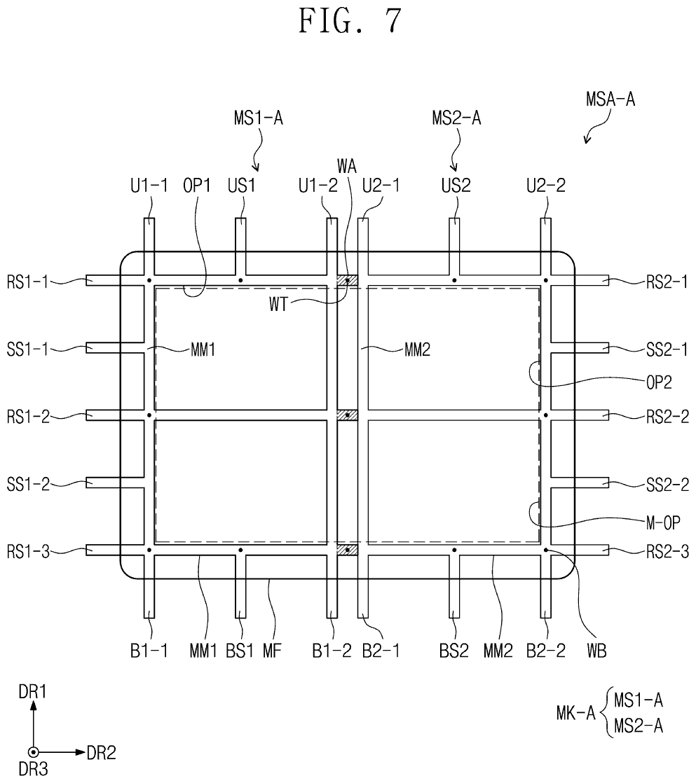

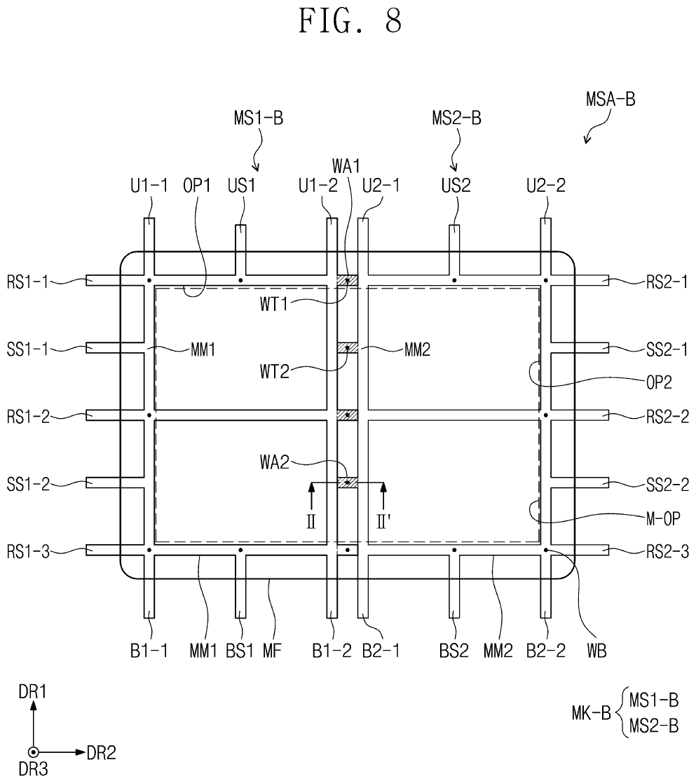

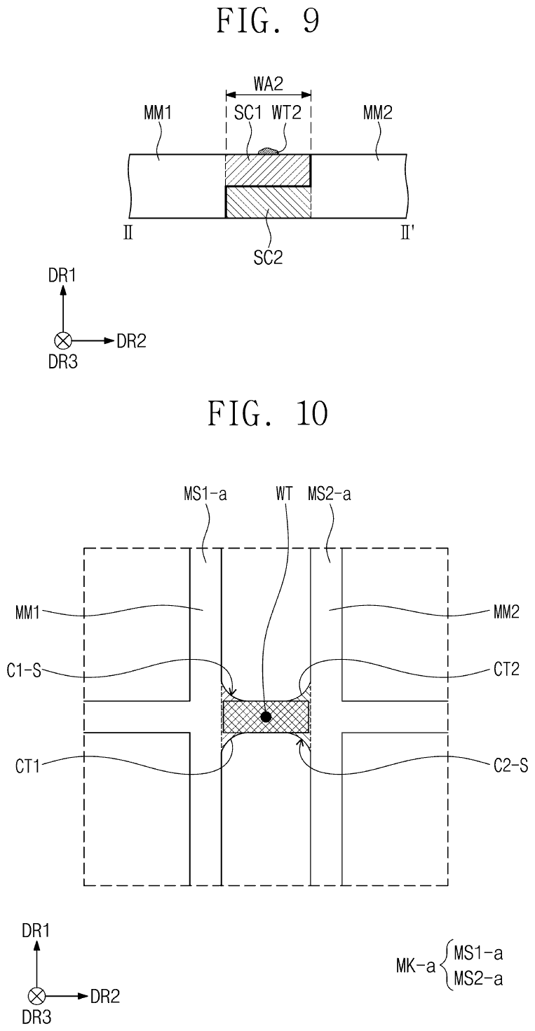

FIG. 7 is a schematic plan view of a mask assembly according to an embodiment. FIG. 8 is a schematic plan view of a mask assembly according to an embodiment. FIG. 9 is a schematic cross-sectional view taken along line II-II′ in FIG. 8. Same/similar reference numbers or symbols refer to the same/similar elements as/to those described with reference to FIGS. 1 to 5, and duplicate description is omitted.

Referring to FIG. 7, a mask assembly MSA-A according to an embodiment may include a mask sheet MK-A and a frame MF. The frame MF may correspond to the frame MF described with reference to FIG. 2A. The mask sheet MK-A may be defined as a state in which multiple masks MS1-A and MS2-A are coupled to each other by welding. The first and second masks MS1-A and MS2-A may be disposed on the frame MF.

The first mask MS1-A may include a first body part MM1, multiple first tension portions U1-1, U1-2, B1-1, B1-2, RS1-1, RS1-2 and RS1-3, and multiple first coupling portions C1-1, C1-2 and C1-3. The first mask MS1-A according to an embodiment may further include first sub-tension portions US1, BS1, SS1-1 and SS1-2.

The first body part MM1 may include at least one first opening OP1 corresponding to a frame opening M-OP. The first opening OP1 may be provided in plurality. The first body part MM1 may have at least one second side overlapping the frame MF, and at least one first side of which at least a portion overlaps the frame opening M-OP.

The first tension portions U1-1, U1-2, B1-1, B1-2, RS1-1, RS1-2 and RS1-3 may protrude from the at least one second side of the first body part MM1. The first upper tension portions U1-1 and U1-2 may protrude in the first direction DR1 from a second side of the first body part MM1 overlapping an upper side of the frame MF, among the at least one second sides of the first body part MM1, which extend in the second direction DR2.

The first lower tension portions B1-1 and B1-2 may protrude in the first direction DR1 from a second side of the first body part MM1 overlapping a lower side of the frame MF, among the at least one second sides of the first body part MM1, which extend in the second direction DR2.

The first lateral tension portions RS1-1, RS1-2 and RS1-3 may protrude in the second direction DR2 from a second side of the first body part MM1, which extends in the first direction DR1. The first lateral tension portions RS1-1, RS1-2 and RS1-3 may be arranged apart from each other in the first direction DR1.

In an embodiment, the first tension portions U1-1, U1-2, B1-1, B1-2, RS1-1, RS1-2 and RS1-3 may not overlap first openings OP1 when viewed in the first direction DR1 and/or the second direction DR2.

Each of first sub-tension portions US1, BS1, SS1-1 and SS1-2 may be disposed between adjacent first tension portions U1-1, U1-2, B1-1, B1-2, RS1-1, RS1-2 and RS1-3.

For example, the first upper sub-tension portion US1 may be disposed between the first-1 upper tension portion U1-1 and a first-2 upper tension portion U1-2, and the first lower sub-tension portion BS1 may be disposed between the first-1 lower tension portion B1-1 and the first-2 lower tension portion B1-2. The first-1 lateral sub-tension portion SS1-1 may be disposed between the first-1 lateral tension portion RS1-1 and the first-2 lateral tension portion RS1-2, and the first-2 lateral sub-tension portion SS1-2 may be disposed between the first-2 lateral tension portion RS1-2 and the first-3 lateral tension portion RS1-3. According to an embodiment, the first sub-tension portions US1, BS1, SS1-1 and SS1-2 may overlap the first openings OP1 when viewed in the first direction DR1 and/or the second direction DR2.

The first sub-tension portions US1, BS1, SS1-1 and SS1-2 may each be a portion to which a structure for tensioning the first mask MS1-A is additionally coupled in coupling of the first mask MS1-A to the frame MF.

The second mask MS2-A may include a second body part MM2, multiple second tension portions U2-1, U2-2, B2-1, B2-2, RS2-1, RS2-2 and RS2-3, and multiple second coupling portions C2-1, C2-2 and C2-3. The second mask MS2-A according to an embodiment may further include second sub-tension portions US2, BS2, SS2-1 and SS2-2.

The second body part MM2 may include at least one second opening OP2 corresponding to the frame opening M-OP. The second opening OP2 may be provided in plurality. The second body part MM2 may have at least one second side(s) overlapping the frame MF, and at least one first side(s) of which at least a portion overlaps the frame opening M-OP.

The second tension portions U2-1, U2-2, B2-1, B2-2, RS2-1, RS2-2 and RS2-3 may protrude from the at least one second sides of the second body part MM2. The second upper tension portions U2-1 and U2-2 may protrude in the first direction DR1 from a second side of the second body part MM2 overlapping the upper side of the frame MF, among the at least one second sides of the second body part MM2, which extend in the second direction DR2.

The second lower tension portions B2-1 and B2-2 may protrude in the first direction DR1 from a second side of the second body part MM2 overlapping the lower side of the frame MF, among the at least one second sides of the second body part MM2, which extend in the second direction DR2.

The second lateral tension portions RS2-1, RS2-2 and RS2-3 may protrude in the second direction DR2 from a second side of the second body part MM2, which extends in the first direction DR1. The second lateral tension portions RS2-1, RS2-2 and RS2-3 may be arranged apart from each other in the first direction DR1.

In an embodiment, the second tension portions U2-1, U2-2, B2-1, B2-2, RS2-1, RS2-2 and RS2-3 may not overlap the second openings OP2 when viewed in the first direction DR1 and/or the second direction DR2.

Each of the second sub-tension portions US2, BS2, SS2-1 and SS2-2 may be disposed between adjacent second tension portions U2-1, U2-2, B2-1, B2-2, RS2-1, RS2-2 and RS2-3.

For example, the second upper sub-tension portion US2 may be disposed between the second-1 upper tension portion U2-1 and the second-2 upper tension portion U2-2, and the second lower sub-tension portion BS2 may be disposed between the second-1 lower tension portion B2-1 and the second-2 lower tension portion B2-2. The second-1 lateral sub-tension portion SS2-1 may be disposed between the second-1 lateral tension portion RS2-1 and the second-2 lateral tension portion RS2-2, and the second-2 lateral sub-tension portion SS2-2 may be disposed between the second-2 lateral tension portion RS2-2 and the second-3 lateral tension portion RS2-3. According to an embodiment, the first sub-tension portions US1, BS1, SS1-1 and SS1-2 may overlap the first openings OP1 when viewed in the first direction DR1 and/or the second direction DR2.

The second sub-tension portions US2, BS2, SS2-1 and SS2-2 may each be a portion to which a structure for tensioning the second mask MS2-A is additionally coupled in coupling of the second mask MS2-A to the frame MF.

The first mask MS1-A may include the first coupling portions C1-1, C1-2 and C1-3 described with reference to FIG. 2B, and the second mask MS2-A may include the second coupling portions C2-1, C2-2 and C2-3 described with reference to FIG. 2B. The first coupling portions C1-1, C1-2 and C1-3 and the second coupling portions C2-1, C2-2 and C2-3 corresponding thereto, may overlap each other to define coupling regions WA, respectively, and may be coupled to each other by performing welding on the coupling regions WA. A coupling welding protrusion WT may be formed in each the coupling regions WA.

Referring to FIGS. 8 and 9, a mask assembly MSA-B according to an embodiment may include a mask sheet MK-B and a frame MF. The frame MF may correspond to the frame MF described with reference to FIG. 2A. The mask sheet MK-B may be defined as a state in which multiple masks MS1-B and MS2-B are coupled to each other by welding. The first and second masks MS1-B and MS2-B may be disposed on the frame MF.

The description of the masks MS1-B and MS2-B included in the mask sheet MK-B may be similar to that of the masks MS1-A and MS2-A of the mask sheet MK-A described with reference to FIG. 7, and will be focused on differences from the description with reference to FIG. 7.

The first mask MS1-B according to an embodiment may further include first sub-coupling portions SC1. The first sub-coupling portions SC1 may be disposed between adjacent first coupling portions C1-1, C1-2 and C1-3 (see FIG. 2B). For example, one first sub-coupling portion SC1 may be disposed between the first-1 coupling portion C1-1 and the first-2 coupling portion C1-2, and the other first sub-coupling portion SC1 may be disposed between the first-2 coupling portion C1-2 and the first-3 coupling portion C1-3. The first sub-coupling portions SC1 may overlap first openings OP1 when viewed in the second direction DR2.

The second mask MS2-B may further include second sub-coupling portions SC2. The second sub-coupling portions SC2 may be disposed on adjacent second coupling portions C2-1, C2-2 and C2-3 (see FIG. 2B). For example, one second sub-coupling portion SC may be disposed between the second-1 coupling portion C2-1 and the second-2 coupling portion C2-2, and the other sub-coupling portion SC1 may be disposed between the second-2 coupling portion C2-2 and the second-3 coupling portion C2-3. The second sub-coupling portions SC2 may overlap second openings OP2 when viewed in the second direction DR2.

In an embodiment, regions in which the first coupling portions C1-1, C1-2 and C1-3 (see FIG. 2B), and the second coupling portions C2-1, C2-2 and C2-3 (see FIG. 2B) corresponding thereto overlap each other may each be defined as a first coupling region WA1, and regions in which the first sub-coupling portions SC1 and second sub-coupling portions SC2 corresponding thereto overlap each other may each be defined as a second coupling region WA2. A first welding protrusion WT1 may be formed in the first coupling region WA1 by welding, and a second welding protrusion WT2 may be formed in the second coupling region WA2 by welding.

According to the embodiments described with reference to FIGS. 7 to 9, as the tension portions and coupling portions overlapping the corresponding openings are further included when viewed in the first direction DR1 and/or the second direction DR2, the masks may be more stably tensioned during the manufacturing of the mask sheet. Accordingly, a sagging defect of the masks may be prevented.

FIG. 10 is an exploded schematic plan view of a portion of a mask sheet according to an embodiment. Same/similar reference numbers or symbols refer to the same/similar elements as/to those described with reference to FIGS. 1 to 5, and duplicate description is omitted.

Referring to FIG. 10, a mask sheet MK-a according to an embodiment may include a first mask MS1-a and a second mask MS2-a.

The first mask MS1-a may include a first body part MM1, a first coupling portion CT1, and the first tension portions described with reference to FIG. 2B. The first coupling portion CT1 may protrude in the second direction MM2 from the at least one first side of the first body part MM1 toward a second body part MM2. A starting portion C1-S of the first coupling portion CT1 according to an embodiment, which protrudes from the first body part MM1, may have a curved shape in a plan view. Accordingly, the first coupling portion C1-1 may have a width in the first direction DR1, which increases from an end of the first coupling portion C1-1 toward the first body part MM1.

The second mask MS2-a may include a second body part MM2, a second coupling portion CT2, and the second tension portions described with reference to FIG. 2B. The second coupling portion CT2 may protrude in the second direction MM2 from the at least one first side of the second body part MM2 toward the first body part MM1. A starting portion C2-S of the second coupling portion CT2 according to an embodiment, which protrudes from the second body part MM2, may have a curved shape in a plan view. Accordingly, the second coupling portion CT2 may have a width in the first direction DR1, which increases from an end of the second coupling portion CT2 toward the second body part MM2.

The first coupling portion CT1 and the second coupling portion CT2 may be coupled by welding, and a welding protrusion WT may be formed in a region in which the first coupling portion CT1 and the second coupling portion CT2 overlap each other.

According to an embodiment, each of the first coupling portion CT1 and the second coupling portion CT2 may have the width increasing from the end toward the corresponding body part MM1 or MM2. Accordingly, in case that the mask sheet MK-a is coupled to the frame MF (see FIG. 2A) in the tensioned state, the applied stress may be prevented from concentrating at the first coupling portion CT1 and the second coupling portion CT2 coupled to each other.

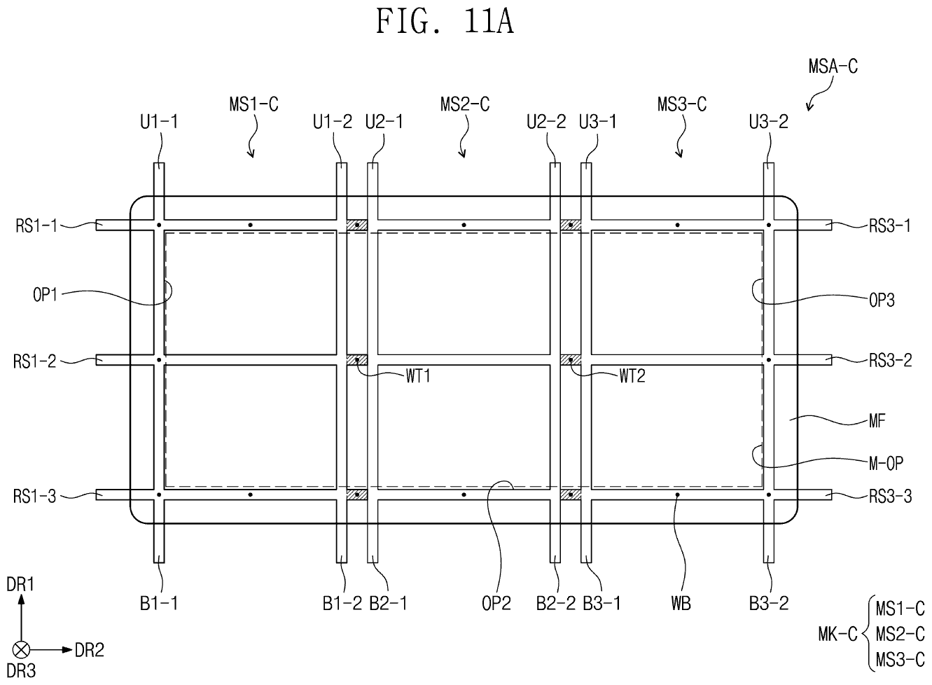

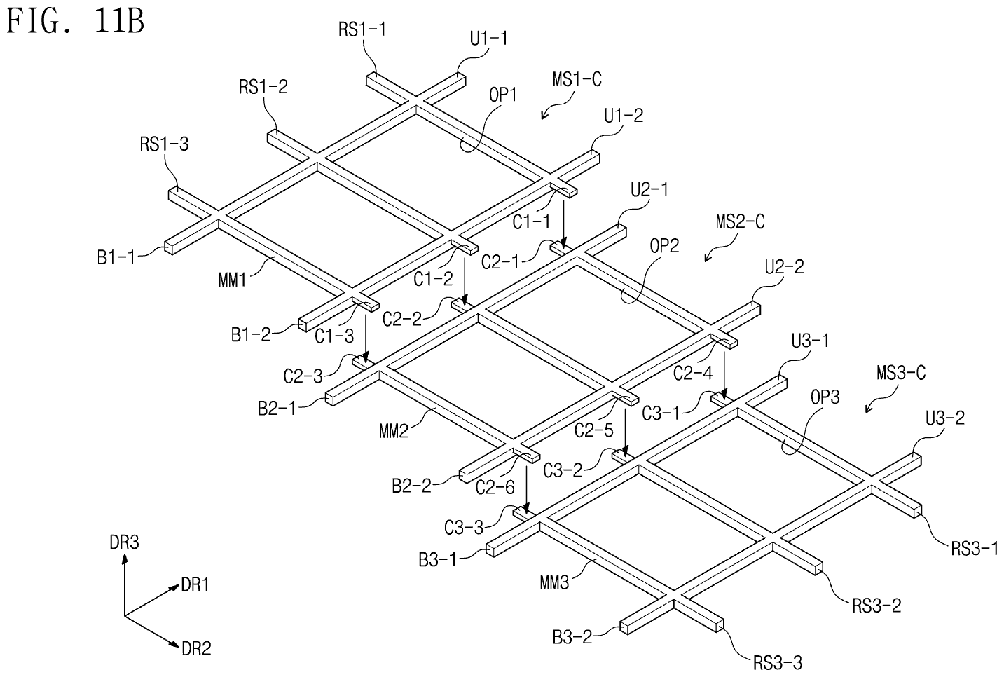

FIG. 11A is a schematic plan view of a mask assembly according to an embodiment. FIG. 11B is a schematic perspective view illustrating masks according to an embodiment. Same/similar reference numbers or symbols refer to the same/similar elements as/to those described with reference to FIGS. 1 to 5, and duplicate description is omitted.

Referring to FIGS. 11A and 11B, a mask assembly MSA-C may include a mask sheet MK-C and a frame MF. The frame MF may correspond to the frame MF described with reference to FIG. 2A. In the disclosure, the mask sheet MK-C may be defined as a state in which multiple masks MS1-C, MS2-C and MS3-C are coupled to each other by welding.

The first mask MS1-C may include a first body part MM1, multiple first tension portions U1-1, U1-2, B1-1, B1-2, RS1-1, RS1-2 and RS1-3, and multiple first coupling portions C1-1, C1-2 and C1-3.

The first body part MM1 may include at least one first opening OP1 corresponding to a frame opening M-OP. The first opening OP1 may be provided in plurality. The first body part MM1 may have at least one second side overlapping the frame MF, and at least one first side of which at least a portion overlaps the frame opening M-OP. The at least one first side of the first body part MM1 may face one of at least one first side(s) of a second body part MM2.

The first tension portions U1-1, U1-2, B1-1, B1-2, RS1-1, RS1-2 and RS1-3 may protrude from the at least one second side of the first body part MM1. The first upper tension portions U1-1 and U1-2 may protrude in the first direction DR1 from a second side of the first body part MM1 overlapping an upper side of the frame MF, among the at least one second sides of the first body part MM1, which extend in the second direction DR2.

The first lower tension portions B1-1 and B1-2 may protrude in the first direction DR1 from a second side of the first body part MM1 overlapping a lower side of the frame MF, among the at least one second sides of the first body part MM1, which extend in the second direction DR2.

The first lateral tension portions RS1-1, RS1-2 and RS1-3 may protrude in the second direction DR2 from a second side of the first body part MM1, which extends in the first direction DR1. The first lateral tension portions RS1-1, RS1-2 and RS1-3 may be arranged apart from each other in the first direction DR1.

The first coupling portions C1-1, C1-2 and C1-3 may protrude from the at least one first side of the first body part MM1, which extends in the first direction DR1. The first coupling portions C1-1, C1-2 and C1-3 may protrude toward at least one first side of a second mask MS2-C.

In an embodiment, the first tension portions U1-1, U1-2, B1-1, B1-2, RS1-1, RS1-2 and RS1-3 may not overlap the first openings OP1 when viewed in the first direction DR1 and/or the second direction DR2.

The third mask MS3-C may include a third body part MM3, multiple third tension portions U3-1, U3-2, B3-1, B3-2, RS3-1, RS3-2 and RS3-3, and multiple third coupling portions C3-1, C3-2 and C3-3.

The third body part MM3 may include at least one third opening OP3 corresponding to the frame opening M-OP. The third opening OP3 may be provided in plurality. The third body part MM3 may have at least one second side overlapping the frame MF, and at least one first side of which at least a portion overlaps the frame opening M-OP. The at least one first side of the third body part MM3 may face at least one first side of the second body part MM2.

The third tension portions U3-1, U3-2, B3-1, B3-2, RS3-1, RS3-2 and RS3-3 may protrude from the at least one second sides of the third body part MM3. The third upper tension portions U3-1 and U3-2 may protrude in the first direction DR1 from a second side of the third body part MM3 overlapping the upper side of the frame MF, among the at least one second sides of the third body part MM3, which extend in the second direction DR2.

The third lower tension portions B3-1 and B3-2 may protrude in the first direction DR1 from a second side of the third body part MM3 overlapping the lower side of the frame MF, among the at least one second sides of the third body part MM3, which extend in the second direction DR2.

The third lateral tension portions RS3-1, RS3-2 and RS3-3 may protrude in the second direction DR2 from a second side of the third body part MM3, which extends in the first direction DR1. The third lateral tension portions RS3-1, RS3-2 and RS3-3 may be arranged apart from each other in the first direction DR1.

The third coupling portions C3-1, C3-2 and C3-3 may protrude from the at least one first side of the third body part MM3, which extends in the first direction DR1. The third coupling portions C3-1, C3-2 and C3-3 may protrude toward the at least one first side of the second mask MS2-C.

In an embodiment, the third tension portions U3-1, U3-2, B3-1, B3-2, RS3-1, RS3-2 and RS3-3 may not overlap the third openings OP3 when viewed in the first direction DR1 and/or the second direction DR2.

The second mask MS2-C may be disposed between the first mask MS1-C and the third mask MS3-C. The second mask MS2-C may include a second body part MM2, multiple second tension portions U2-1, U2-2, B2-1 and B2-2, and multiple second coupling portions C2-1, C2-2, C2-3, C2-4, C2-5 and C2-6.

The second body part MM2 may include at least one second opening OP2 corresponding to the frame opening M-OP. The second opening OP2 may be provided in plurality. According to an embodiment, the openings OP1, OP2 and OP3, which are included in the first to third body parts MM1, MM2 and MM3, respectively, may be arranged in the same matrix shape of 2 rows and 1 column. However, the disclosure is not limited thereto, and the openings included in at least one body part of the first to third body parts MM1, MM2 and MM3 may be arranged in a different shape from the openings included in the other body parts.

In the second body part MM2, at least one second side extending in the first direction DR1 may overlap the frame MF, and at least one first side extending in the second direction DR2 may each have at least a portion overlapping the frame opening M-OP. At least one first side of the second body part MM2 may face at least one first side of the first body part MM1, and at least one first side of the second body part MM2 may face at least one side of the third body part MM3.

The second upper tension portions U2-1 and U2-2 may protrude in the first direction DR1 from at least one second side of the second body part MM2 overlapping the upper side of the frame MF, among the at least one second sides of the second body part MM2.

The second lower tension portions B2-1 and B2-2 may protrude in the first direction DR1 from at least one second side of the second body part MM2 overlapping the lower side of the frame MF, among the at least one second sides of the second body part MM2.

The second coupling portions C2-1, C2-2, C2-3, C2-4, C2-5 and C2-6 may protrude from the at least one first side of the second body part MM2, which extend in the first direction DR1. The second-1 to second-3 coupling portions C2-1, C2-2 and C2-3 may protrude toward the at least one first side of the first mask MS1-C, and the second-4 to second-6 coupling portions C2-4, C2-5 and C2-6 may protrude toward the at least one first side of the third mask MS3-C.

The first-1 coupling portion C1-1 may overlap the second-1 coupling portion C2-1, the first-2 coupling portion C1-2 may overlap the second-2 coupling portion C2-2, and the first-3 coupling portion C1-3 may overlap the second-3 coupling portion C2-3. The coupling portions of the first mask MS1-C and the second mask MS2-C may be coupled to each other by welding in regions in which the coupling portions overlap each other. Accordingly, a first welding protrusion WT1 may be formed in each of the regions in which the coupling portions overlap each other.

The third-1 coupling portion C3-1 may overlap the second-4 coupling portion C2-4, the third-2 coupling portion C3-2 may overlap the second-5 coupling portion C2-5, and the third-3 coupling portion C3-3 may overlap the second-6 coupling portion C2-6. The coupling portions of the third mask MS3-C and the second mask MS2-C may be coupled to each other by welding in regions in which the coupling portions overlap each other. Accordingly, a second welding protrusion WT2 may be formed in each of the regions in which the coupling portions overlap each other.

As in this embodiment, an intermediate mask disposed between the masks MS1-C and MS3-C, which are disposed at ends of the frame MF, respectively, may have a shape corresponding to the second mask MS2-C. The intermediate mask may be provided in plurality and the intermediate masks may each have a shape corresponding to the second mask MS2-C.

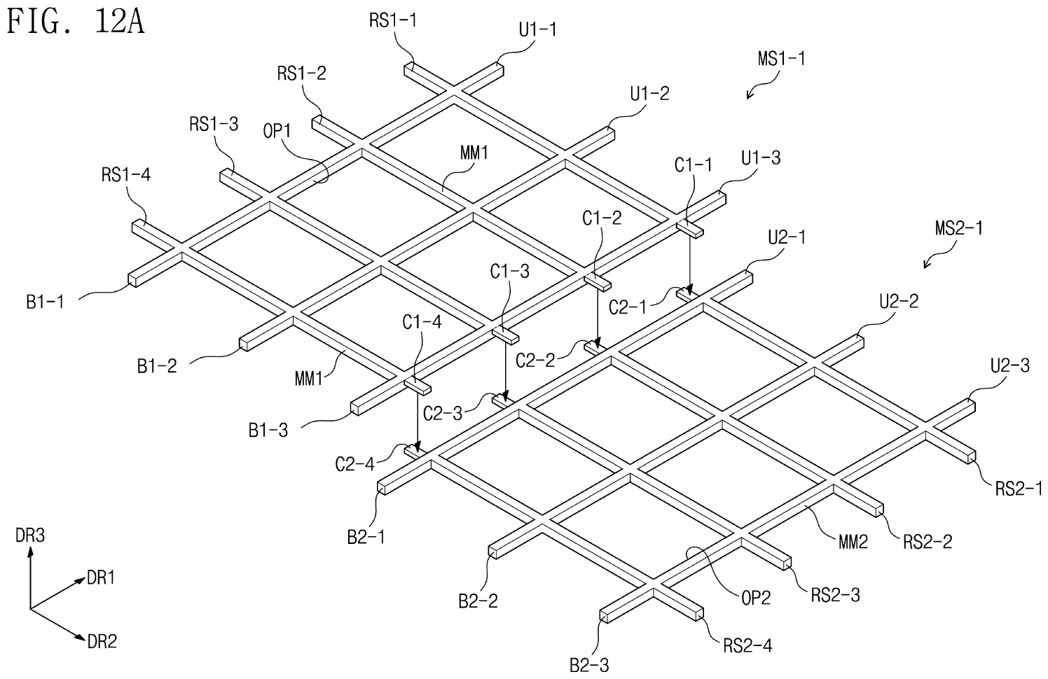

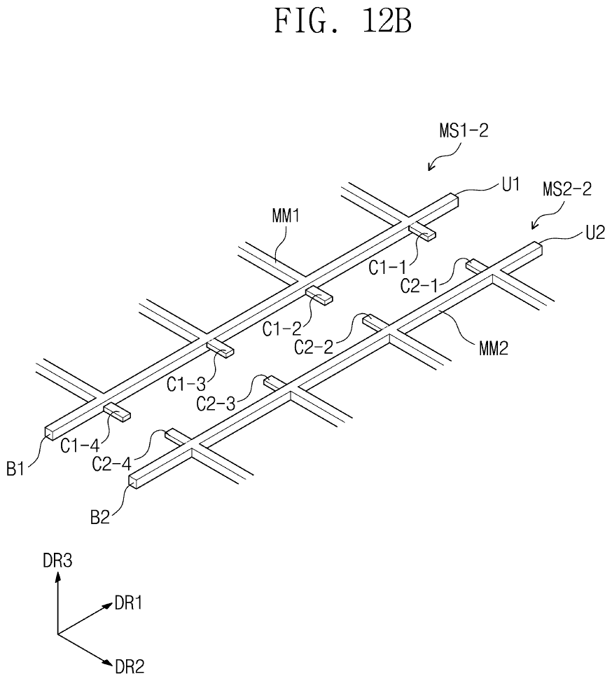

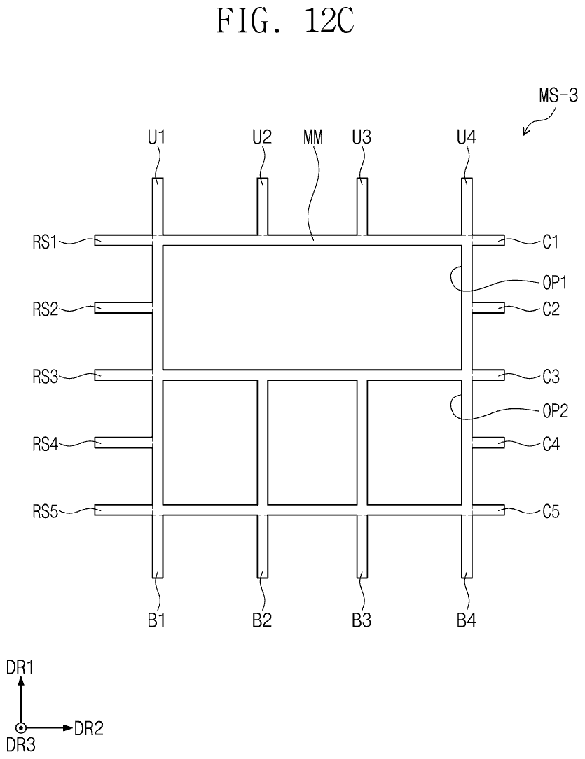

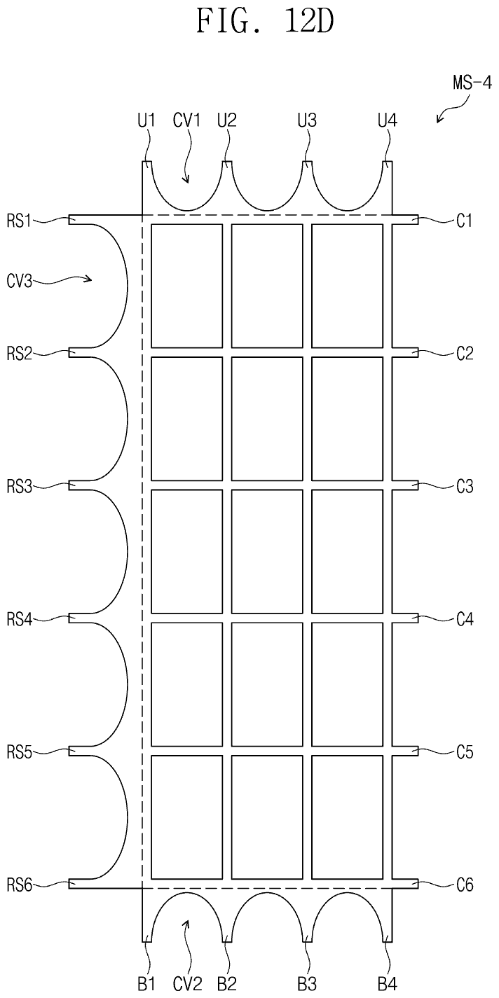

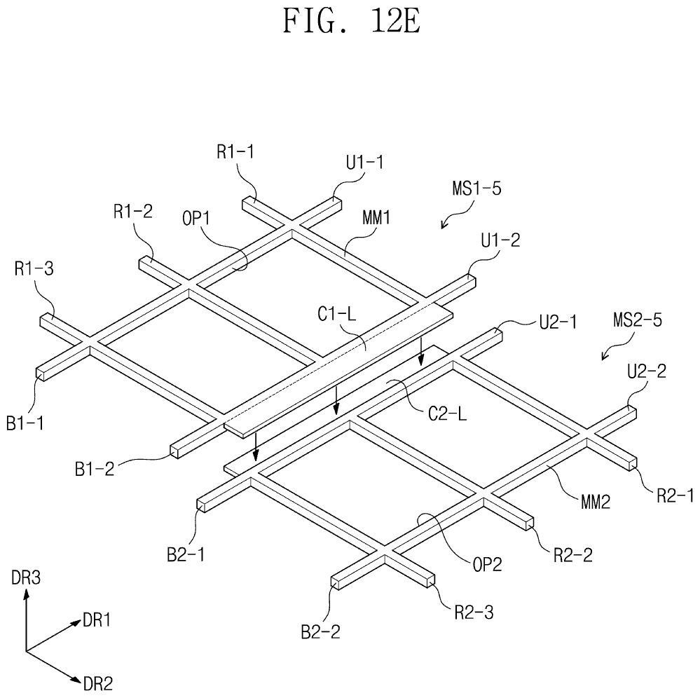

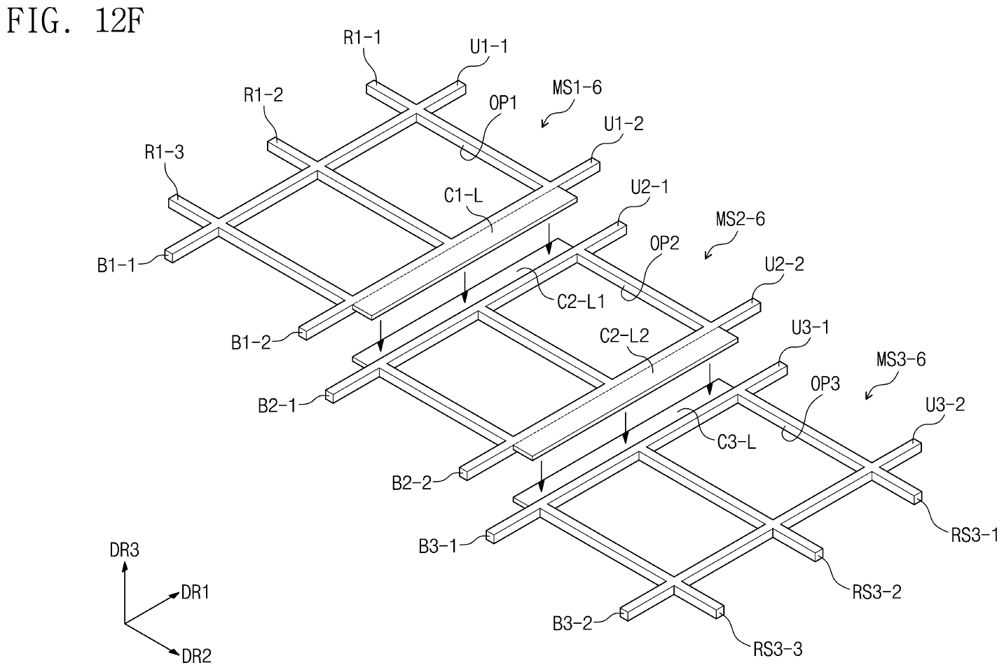

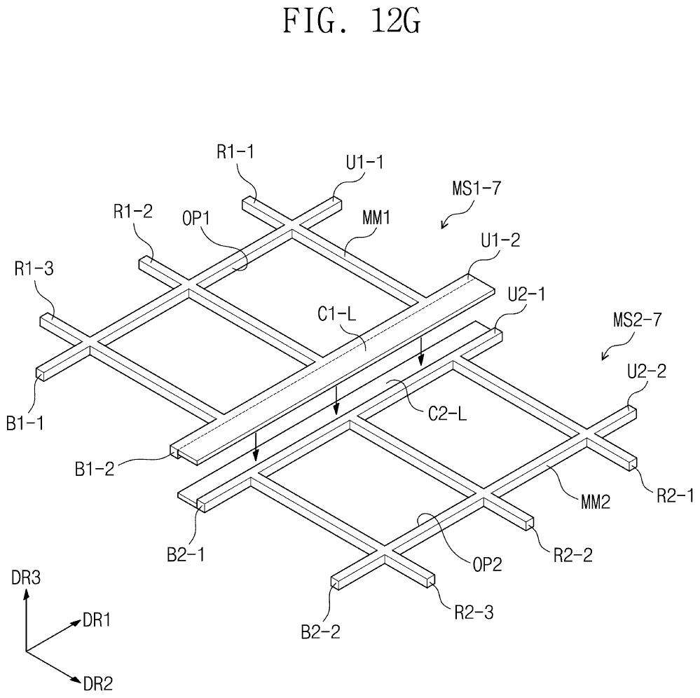

FIG. 12A is a schematic perspective view illustrating masks according to an embodiment. FIG. 12B is an exploded schematic perspective view of a portion of masks according to an embodiment. FIG. 12C is a schematic plan view of a mask according to an embodiment. FIG. 12D is a schematic plan view of a mask according to an embodiment. 12E is a perspective view illustrating masks according to an embodiment of the inventive concept. FIG. 12F is a perspective view illustrating masks according to an embodiment of the inventive concept. Same/similar reference numbers or symbols refer to the same/similar elements as/to those described with reference to FIGS. 1 to 5, and duplicate description is omitted.

Referring to FIG. 12A, a first mask MS1-1 according to an embodiment may include a first body part MM1, multiple first tension portions U1-1, U1-2, U1-3, B1-1, B1-2, B1-3, RS1-1, RS1-2, RS1-3 and RS1-4, and multiple first coupling portions C1-1, C1-2, C1-3 and C1-4.

The first body part MM1 may include at least one first opening OP1 corresponding to a frame opening M-OP. The first opening OP1 may be provided in plurality. The first body part MM1 may include six first openings OP1 arranged in a matrix shape of 3 rows and 2 columns.

According to an embodiment, each of the number of the first upper tension portions U1-1, U1-2 and U1-3 and the number of the first lower tension portions B1-1, B1-2 and B1-3 may be greater by one than the two columns in the matrix shape of the first openings OP1.

Each of the number of the first lateral tension portions RS1-1, RS1-2, RS1-3 and RS1-4 and the number of the first coupling portions C1-1, C1-2, C1-3 and C1-4 may be greater by one than the three rows in the matrix shape of the first openings OP1.

The second mask MS2-1 may include a second body part MM2, multiple second tension portions U2-1, U2-2, U2-3, B2-1, B2-2, B2-3, RS2-1, RS2-2, RS2-3 and RS2-4, and multiple second coupling portions C2-1, C2-2, C2-3 and C2-4. The second coupling portions C2-1, C2-2, C2-3 and C2-4 may overlap the first coupling portions C1-1, C1-2, C1-3 and C1-4 corresponding thereto, respectively.

The second body part MM2 may include at least one second opening OP2 corresponding to the frame opening M-OP. The second opening OP2 may be provided in plurality. The second body part MM2 includes six second openings OP2 arranged in a matrix shape of 3 rows and 2 columns.

According to an embodiment, each of the number of the second upper tension portions U2-1, U2-2 and U2-3 and the number of the second lower tension portions B2-1, B2-2 and B2-3 may be greater by one than the two columns in the matrix shape of the second openings OP2.

Each of the number of the second lateral tension portions RS2-1, RS2-2, RS2-3 and RS2-4 and the number of the second coupling portions C2-1, C2-2, C2-3 and C2-4 may be greater by one than the three columns in the matrix shape of the second openings OP2.

According to an embodiment, the number of the openings included in each of the first and second masks MS1-1 and MS2-1 may be arranged in a matrix shape of n rows×m columns. Each of the numbers of the upper tension portions and the lower tension portions, which are included in each of the first and second masks MS1-1 and MS2-1, may be greater by at least one than m columns, and each of the numbers of the lateral tension portions and the coupling portions may be greater by at least one than n rows.

Referring to FIG. 12B, the first mask MS1-2 according to an embodiment may include the first coupling portions C1-1, C1-2, C1-3 and C1-4, which protrude from at least one first side of the first body part MM1 toward at least one first side of the second body part MM2, and first tension portions U1 and B1. The first coupling portions C1-1, C1-2, C1-3 and C1-4 may include a first-1 group of coupling portions C1-1 and C1-3 protruding from the at least one first side of the first body part MM1 at a first height, and a first-2 group of coupling portions C1-2 and C1-4 protruding from the at least one first side of the first body part MM1 at a second height. The first height may be different from the second height. The first-1 group of coupling portions C1-1 and C1-3 and the first-2 group of coupling portions C1-2 and C1-4 may be disposed alternately with each other. According to an embodiment, the first-1 group of coupling portions C1-1 and C1-3 and the first-2 group of coupling portions C1-2 and C1-4 may not overlap each other when viewed in the first direction DR1.

The second mask MS2-2 may include the second coupling portions C2-1, C2-2, C2-3 and C2-4 and C1-4, which protrude from the at least one first side of the second body part MM2 toward the at least one first side of the first body part MM1, and tension portions U2 and B2. The second coupling portions C2-1, C2-2, C2-3 and C2-4 may include a second-1 group of coupling portions C2-1 and C2-3 protruding from the at least one side of the second body part MM2 at a second height, and a second-2 group of coupling portions C2-2 and C2-4 protruding from the at least one first side of the second body part MM2 at a first height. The first height may be different from the second height. The second-1 group of coupling portions C2-1 and C2-3 and the second-2 group of coupling portions C2-2 and C2-4 may be disposed alternately with each other. According to an embodiment, the second-1 group of coupling portions C2-1 and C2-3 and the second-2 group of coupling portions C2-2 and C2-4 may not overlap from each other when viewed in the first direction DR1.

In case of moving the first mask MS1-2 and the second mask MS2-2 in the second direction DR2, the first-1 group of coupling portions C1-1 and C1-3 and the second-1 group of coupling portions C2-1 and C2-3 may be coupled to each other, and the first-2 group of coupling portions C1-2 and C1-4 and the second-2 group of coupling portions C2-2 and C2-4 may be coupled to each other.

Referring to FIG. 12C, a mask MS-3 according to an embodiment may include upper tension portions U1, U2, U3 and U4, lower tension portions B1, B2, B3 and B4, lateral tension portions RS1, RS2, RS3, RS4 and RS5, and coupling portions C1, C2, C3, C4 and C5. The coupling portions C1, C2, C3, C4 and C5 may be portions coupled to adjacent portions protruding from a body part of an adjacent mask.

A body part MM according to this embodiment may include openings OP1 and OP2 having different areas. For example, the openings OP1 and OP2 having different shapes may be included in one mask MS-3. One first opening OP1 having a first area may be provided, and multiple second openings OP2 having a second area smaller than the first area may be provided. However, the disclosure is not limited thereto, and three or more types of openings, which have different areas, may be included in the one mask MS-3.

Referring to FIG. 12D, a mask MS-4 according to an embodiment may include upper tension portions U1, U2, U3 and U4, lower tension portions B1, B2, B3 and B4, lateral tension portions RS1, RS2, RS3, RS4, RS5 and RS6, and coupling portions C1, C2, C3, C4, C5 and C6. The coupling portions C1, C2, C3, C4, C5 and C6 may be portions coupled to adjacent portions protruding from a body part of an adjacent mask. The mask MS-4 according to an embodiment may include openings arranged in a matrix shape of 5 rows and 3 columns.

According to an embodiment, curvature portions CV1, CV2 and CV3 recessed toward the inside of the mask MS-4 may be included between adjacent tension portions. The curvature portions CV1, CV2 and CV3 may each have a curved shape in a plan view.

The first curvature portion CV1 may be disposed between two adjacent upper tension portions among the upper tension portions U1, U2, U3 and U4. The second curvature portion CV2 may be disposed between two adjacent lower tension portions among the lower tension portions B1, B2, B3 and B4. The third curvature portion CV3 may be disposed between two adjacent lateral tension portions among the lateral tension portions RS1, RS2, RS3, RS4, RS5 and RS6. However, the disclosure is not limited thereto, and the third curvature portion CV3 may be omitted.

According to an embodiment, the mask MS-4 may include the tension portions, each of which has a width increasing toward the inside of the mask MS-4, to reduce concentration of stress applied during tensioning of the tension portions through a structure. Accordingly, the mask MS-4 may be more stably tensioned.

Referring to FIG. 12E, a first mask MS1-5 according to an embodiment may include a first body part MM1, a plurality of first tension portions U1-1, U1-2, B1-1, B1-2, R1-1, R1-2 and R1-3, and one first coupling portion C1-L. The first body part MM1, the plurality of first tension portions U1-1, U1-2, B1-1, B1-2, R1-1, R1-2 and R1-3, and the first coupling portion C1-L are provided as a substantially integral structure, but will be separately described for convenience of explanation.

The first body part MM1 may include at least one first opening portion OP1 corresponding to the frame opening portion M-OP (see FIG. 2A). The first opening portion OP1 may be provided in plurality. FIG. 12E exemplarily illustrates that the first body part MM1 includes two first opening portions OP1 arranged in a matrix shape of 2 rows and 1 column. The first body part MM1 may have one sides overlapping the frame MF (see FIG. 2A), and the other side of which at least a portion overlaps the frame opening portion M-OP (see FIG. 2A).

The first tension portions U1-1, U1-2, B1-1, B1-2, R1-1, R1-2 and R1-3 may protrude from the one sides of the first body part MM1. The first tension portions U1-1, U1-2, B1-1, B1-2, R1-1, R1-2 and R1-3 may each be a portion to which a structure for tensioning the first mask MS1-5 is coupled in coupling of the first mask MS1-5 to the frame MF (see FIG. 2A).

The first tension portions U1-1, U1-2, B1-1, B1-2, R1-1, R1-2 and R1-3 may protrude from the first body part MM1 in the first direction DR1 and the second direction DR2.

In this embodiment, the first tension portions U1-1, U1-2, B1-1, B1-2, R1-1, R1-2 and R1-3 may not overlap the first opening portions OP1 when viewed in the first direction DR1 and the second direction DR2. Accordingly, even when each of the first tension portions U1-1, U1-2, B1-1, B1-2, R1-1, R1-2 and R1-3 is connected to the structure and tensioned in a predetermined direction, the shapes of the first opening portions OP1 may be maintained.

The first mask MS1-5 may include the first coupling portion C1-L. The first coupling portion C1-L may protrude in the second direction DR2 from one side of the first body part MM1, which does not overlap the frame opening portion M-OP (see FIG. 2A). According to an embodiment, the first coupling portion C1-L may extend in the first direction DR1, and the first coupling portion C1-L may overlap the first opening portions OP1 when viewed in the second direction DR2.

A second mask MS2-5 according to an embodiment may include a second body part MM2, a plurality of second tension portions U2-1, U2-2, B2-1, B2-2, R2-1, R2-2 and R2-3, and one second coupling portion C2-L. The second body part MM2, the plurality of second tension portions U2-1, U2-2, B2-1, B2-2, R2-1, R2-2 and R2-3, and the second coupling portion C2-L are provided as a substantially integral structure, but will be separately described for convenience of explanation.

The second body part MM2 may include at least one second opening portion OP2 corresponding to the frame opening portion M-OP (see FIG. 2A). The second opening portion OP2 may be provided in plurality. FIG. 12E exemplarily illustrates that the second body part MM2 includes two second opening portions OP2 arranged in a matrix shape of 2 rows and 1 column. According to an embodiment, the arrangement shape of the first opening portions OP1 included in the first body part MM1 may be the same as the arrangement shape of the second opening portions OP2 included in the second body part MM2.

The second body part MM2 may have one sides overlapping the frame MF (see FIG. 2A), and the other side of which at least a portion overlaps the frame opening portion M-OP (see FIG. 2A).

The second tension portions U2-1, U2-2, B2-1, B2-2, R2-1, R2-2 and R2-3 may protrude from the second body part MM2 in the first direction DR1 and the second direction DR2.

The second tension portions U2-1, U2-2, B2-1, B2-2, R2-1, R2-2 and R2-3 may each be a portion to which a structure for tensioning the second mask MS2-5 is coupled in coupling of the second mask MS2-5 to the frame MF (see FIG. 2A).

In this embodiment, the second tension portions U2-1, U2-2, B2-1, B2-2, R2-1, R2-2 and R2-3 may not overlap the second opening portions OP2 when viewed in the first direction DR1 and the second direction DR2. Accordingly, even when each of the second tension portions U2-1, U2-2, B2-1, B2-2, R2-1, R2-2 and R2-3 is connected to the structure and tensioned in a predetermined direction, the shapes of the second opening portions OP2 may be maintained.

A width of each of the tension portions included in the first mask MS1-5 and the second mask MS2-5 described above in a direction crossing the protruding direction of each of the tension portions may be about 15 mm to about 50 mm.

The second mask MS2-5 may include the second coupling portion C2-L. The second coupling portion C2-L may protrude in the second direction DR2 from one side of the second body part MM2, which does not overlap the frame opening portion M-OP (see FIG. 2A). According to an embodiment, the second coupling portion C2-L may extend in the first direction DR1, and the second coupling portion C2-L may overlap the second opening portions OP2 when viewed in the second direction DR2.

The first coupling portion C1-L and the second coupling portion C2-L may overlap each other in the third direction DR3. The first coupling portion C1-L may protrude from an upper side of the first body part MM1 in the second direction DR2, and the second coupling portion C2-L may protrude from a lower side of the second body part MM2 in the second direction DR2.

A surface, from which the first coupling portion C1-L protrudes, of the first body part MM1 and a surface, from which the second coupling portion C2-L protrudes, of the second body part MM2 may face each other in the second direction DR2. The first coupling portion C1-L and the second coupling portion C2-L may be coupled to each other by welding. That is, the welding may be performed in a state in which a bottom surface of the first coupling portion C1-L and a top surface of the second coupling portion C2-L are in entire contact with each other.

A thickness of the first coupling portion C1-L and the second coupling portion C2-L, which are coupled to each other, may be less than or equal to a thickness of each of the first body part MM1 and the second body part MM2.

According to this embodiment, as a contact area at which the different masks MS1-5 and MS2-5 are coupled to each other increases, the masks MS1-5 and MS2-5 may be stably coupled to each other.

Referring to FIG. 12F, a first mask MS1-6 may include a first body part MM1, a plurality of first tension portions U1-1, U1-2, B1-1, B1-2, R1-1, R1-2 and R1-3, and one first coupling portion C1-L. A second mask MS2-6 may include a second body part MM2, a plurality of second tension portions U2-1, U2-2, B2-1 and B2-2, and two second coupling portions C2-L1 and C2-L2.

The first coupling portion C1-L may protrude in the second direction DR2 from one side of the first body part MM1, which does not overlap the frame opening portion M-OP (see FIG. 2A). According to an embodiment, the first coupling portion C1-L may extend in the first direction DR1, and the first coupling portion C1-L may overlap first opening portions OP1 when viewed in the second direction DR2.

The second mask MS2-6 may include the second coupling portions C2-L1 and C2-L2. A second-1 coupling portion C2-L1 may protrude in the second direction DR2 facing the first mask MS1-6. A second-2 coupling portion C2-L2 may protrude in the second direction DR2 facing a third mask MS3-6. According to an embodiment, each of the second coupling portions C2-L1 and C2-L2 may extend in the first direction DR1, and the second coupling portions C2-L1 and C2-L2 may overlap second opening portions OP2 when viewed in the second direction DR2. The second-1 coupling portion C2-L1 and the second-2 coupling portion C2-L2 may be spaced apart from each other with the second opening portions OP2 therebetween.

A third coupling portion C3-L may protrude in the second direction DR2 from one side of a third body part MM3, which does not overlap the frame opening portion M-OP (see FIG. 2A). According to an embodiment, the third coupling portion C3-L may extend in the first direction DR1, and the third coupling portion C3-L may overlap third opening portions OP3 when viewed in the second direction DR2.

The first coupling portion C1-L and the second-1 coupling portion C2-L1 may overlap each other in the third direction DR3. The first coupling portion C1-L may protrude from an upper side of the first body part MM1 in the second direction DR2, and the second-1 coupling portion C2-L1 may protrude from a lower side of the second body part MM2 in the second direction DR2.

The third coupling portion C3-L and the second-2 coupling portion C2-L2 may overlap each other in the third direction DR3. The third coupling portion C3-L may protrude from a lower side of the third body part MM3 in the second direction DR2, and the second-2 coupling portion C2-L2 may protrude from an upper side of the second body part MM2 in the second direction DR2.

A surface, from which the first coupling portion C1-L protrudes, of the first body part MM1 and a surface, from which the second-1 coupling portion C2-L1 protrudes, of the second body part MM2 may face each other in the second direction DR2. The first coupling portion C1-L and the second-1 coupling portion C2-L1 may be coupled to each other by welding. That is, the welding may be performed in a state in which a bottom surface of the first coupling portion C1-L and a top surface of the second-1 coupling portion C2-L1 are in entire contact with each other.

In addition, a surface, from which the third coupling portion C3-L protrudes, of the third body part MM3 and a surface, from which the second-2 coupling portion C2-L2 protrudes, of the second body part MM2 may face each other in the second direction DR2. The third coupling portion C3-L and the second-2 coupling portion C2-L2 may be coupled to each other by welding. That is, the welding may be performed in a state in which a top surface of the third coupling portion C3-L and a bottom surface of the second-2 coupling portion C2-L2 are in entire contact with each other.

According to this embodiment, as a contact area at which the different masks MS1-6, MS2-6 and MS3-6 are coupled to each other increases, the masks MS1-6, MS2-6 and MS3-6 may be stably coupled to each other.

Referring to FIG. 12G, a first mask MS1-7 according to an embodiment may include a first body part MM1, a plurality of first tension portions U1-1, U1-2, B1-1, B1-2, R1-1, R1-2 and R1-3, and a first coupling portion C1-L. The first body part MM1, the plurality of first tension portions U1-1, U1-2, B1-1, B1-2, R1-1, R1-2 and R1-3, and the first coupling portion C1-L are provided as a substantially integral structure, but will be separately described for convenience of explanation.

The first body part MM1 may include at least one first opening portion OP1 corresponding to the frame opening portion M-OP (see FIG. 2A). The first opening portion OP1 may be provided in plurality. FIG. 12G exemplarily illustrates that the first body part MM1 includes two first opening portions OP1 arranged in a matrix shape of 2 rows and 1 column. The first body part MM1 may have one sides overlapping the frame MF (see FIG. 2A), and the other side of which at least a portion overlaps the frame opening portion M-OP (see FIG. 2A).

The first tension portions U1-1, U1-2, B1-1, B1-2, R1-1, R1-2 and R1-3 may protrude from the one sides of the first body part MM1. The first tension portions U1-1, U1-2, B1-1, B1-2, R1-1, R1-2 and R1-3 may each be a portion to which a structure for tensioning the first mask MS1-7 is coupled in coupling of the first mask MS1-7 to the frame MF (see FIG. 2A).

The first tension portions U1-1, U1-2, B1-1, B1-2, R1-1, R1-2 and R1-3 may protrude from the first body part MM1 in the first direction DR1 and the second direction DR2.

The first-2 upper tension portion U1-2 and the first-2 lower tension portion B1-2 may be spaced apart in the first direction DR1 with the first body part MM1 interposed therebetween. Among the first tension portions U1-1, U1-2, B1-1, B1-2, R1-1, R1-2, and R1-3, the first-2 upper tension portion U1-2 and the first-2 lower tension portion B1-2 may be disposed closest to the second mask MS2-7.

In this embodiment, the first tension portions U1-1, U1-2, B1-1, B1-2, R1-1, R1-2 and R1-3 may not overlap the first opening portions OP1 when viewed in the first direction DR1 and the second direction DR2. Accordingly, even when each of the first tension portions U1-1, U1-2, B1-1, B1-2, R1-1, R1-2 and R1-3 is connected to the structure and tensioned in a predetermined direction, the shapes of the first opening portions OP1 may be maintained.

The first mask MS1-7 may include the first coupling portion C1-L. The first coupling portion C1-L may protrude in the second direction DR2 from one side of the first body part MM1, which does not overlap the frame opening portion M-OP (see FIG. 2A). According to an embodiment, the first coupling portion C1-L may extend in the first direction DR1, and the first coupling portion C1-L may overlap the first opening portions OP1 when viewed in the second direction DR2.

In this embodiment, the first coupling portion C1-L may protrude from one sides of the first-2 upper tension portion U1-2, the first-2 lower tension portion B1-2, and the first body part MM1 disposed between the tension portions U1-2 and B1-2 in the first direction DR1.

In the third direction DR3, the thickness of the first coupling portion C1-L may be smaller than the thickness of the tension portions U1-2 and B1-2 and the first body part MM1. A second mask MS2-7 according to an embodiment may include a second body part MM2, a plurality of second tension portions U2-1, U2-2, B2-1, B2-2, R2-1, R2-2 and R2-3, and one second coupling portion C2-L. The second body part MM2, the plurality of second tension portions U2-1, U2-2, B2-1, B2-2, R2-1, R2-2 and R2-3, and the second coupling portion C2-L may be provided as a substantially integral structure, but will be separately described for convenience of explanation.

The second body part MM2 may include at least one second opening portion OP2 corresponding to the frame opening portion M-OP (see FIG. 2A). The second opening portion OP2 may be provided in plurality. FIG. 12G exemplarily illustrates that the second body part MM2 includes two second opening portions OP2 arranged in a matrix shape of 2 rows and 1 column. According to an embodiment, the arrangement shape of the first opening portions OP1 included in the first body part MM1 may be the same as the arrangement shape of the second opening portions OP2 included in the second body part MM2.

The second body part MM2 may have one sides overlapping the frame MF (see FIG. 2A), and the other side of which at least a portion overlaps the frame opening portion M-OP (see FIG. 2A).

The second tension portions U2-1, U2-2, B2-1, B2-2, R2-1, R2-2 and R2-3 may protrude from the second body part MM2 in the first direction DR1 and the second direction DR2.

The second-1 upper tension portion U2-1 and the second-1 lower tension portion B2-1 may be spaced apart along the first direction DR1 with the second body part MM2 interposed therebetween. Among second tension portions U2-1, U2-2, B2-1, B2-2, R2-1, R2-2 and R2-3, the second-1 upper tension portion U2-1 and the second-1 lower tension portion B2-1 may be disposed closest to the first mask MS1-7.

The first-2 upper tension portion U1-2 and the second-1 upper tension portion U2-1 may face each other in the second direction DR2, and first-2 lower tension portion B1-2 and second-1 lower tension portion B2-1 may face each other in the second direction DR2.

The second tension portions U2-1, U2-2, B2-1, B2-2, R2-1, R2-2 and R2-3 may each be a portion to which a structure for tensioning the second mask MS2-7 is coupled in coupling of the second mask MS2-7 to the frame MF (see FIG. 2A).

In this embodiment, the second tension portions U2-1, U2-2, B2-1, B2-2, R2-1, R2-2 and R2-3 may not overlap the second opening portions OP2 when viewed in the first direction DR1 and the second direction DR2. Accordingly, even when each of the second tension portions U2-1, U2-2, B2-1, B2-2, R2-1, R2-2 and R2-3 is connected to the structure and tensioned in a predetermined direction, the shapes of the second opening portions OP2 may be maintained.

A width of each of the tension portions included in the first mask MS1-7 and the second mask MS2-7 described above in a direction crossing the protruding direction of each of the tension portions may be about 15 mm to about 50 mm.

The second mask MS2-7 may include the second coupling portion C2-L. The second coupling portion C2-L may protrude in the second direction DR2 from one side of the second body part MM2, which does not overlap the frame opening portion M-OP (see FIG. 2A). According to an embodiment, the second coupling portion C2-L may extend in the first direction DR1, and the second coupling portion C2-L may overlap the second opening portions OP2 when viewed in the second direction DR2.

In this embodiment, the second coupling portion C2-L may protrude from one sides of second-1 upper tension portion U2-1 and the second-1 lower tension portion B2-1, and the second body part MM2 disposed between the tension portions U2-1 and B2-1 in the first direction DR1.

In the third direction DR3, the thickness of the second coupling portion C2-L may be smaller than the thickness of the tension portions U2-1 and B2-1 and the second body part MM2. The first coupling portion C1-L and the second coupling portion C2-L may overlap each other in the third direction DR3. The first coupling portion C1-L may protrude from an upper side each of the first body part MM1, the tension portions U1-2 and B1-2 in the second direction DR2, and the second coupling portion C2-L may protrude from a lower side each of the second body part MM2, tension portions U2-1 and B2-1 in the second direction DR2.

A bottom surface of first coupling portion C1-L and an upper surface of the second coupling portion C2-L may contact with each other in the second direction DR2. The first coupling portion C1-L and the second coupling portion C2-L may be coupled to each other by welding. That is, the welding may be performed in a state in which a bottom surface of the first coupling portion C1-L and a top surface of the second coupling portion C2-L are in entire contact with each other.

In an embodiment, a coupling region overlapping the first coupling portion C1-L and the second coupling portion C2-L, which overlap each other, may have a width of about 500 μm to about 5 mm in the first direction.

In an embodiment, each of the first coupling portion C1-L and the second coupling portion C2-L may have a rectangular shape extending along the first direction DR1.

A thickness of the first coupling portion C1-L and the second coupling portion C2-L, which are coupled to each other, may be less than or equal to a thickness of each of the first body part MM1 and the second body part MM2 and a thickness of each of the tension portions U1-2, U2-1, B1-2, and B2-1.

In the first direction DR1, a width of the tension portions U1-2 and B1-2 and the first body part MM1 disposed between the tension portions U1-2 and B1-2 may be the same as a width of the first coupling portion C1-L. In addition, a width of the tension portions U2-1 and B2-1 and the first body part MM2 disposed between the tension portions U2-1 and B2-1 may be the same as a width of the second coupling portion C2-L.

According to this embodiment, as a contact area at which the different masks MS1-7 and MS2-7 are coupled to each other increases, the masks MS1-7 and MS2-7 may be stably coupled to each other. The coupling portions C1-L and C2-L described in this embodiment can also be applied to the masks MS1-6, MS-26, and MS-3-6 described in FIG. 12F.

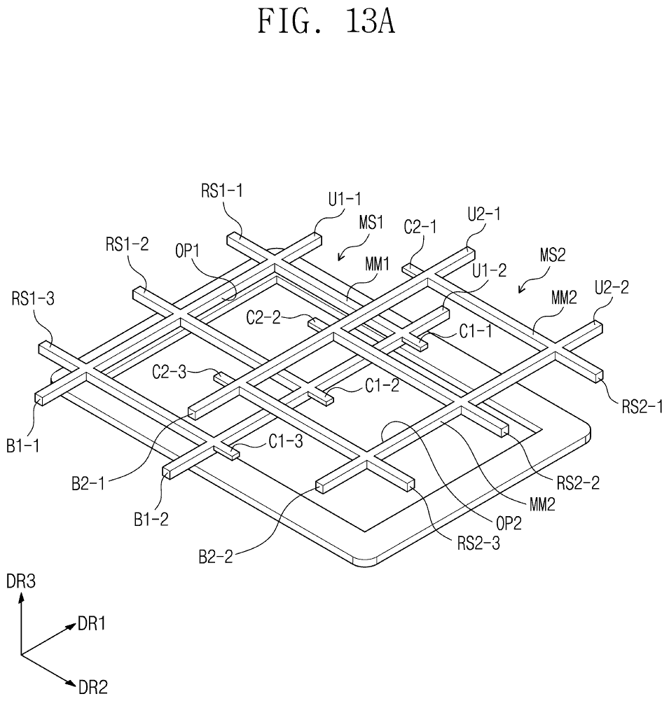

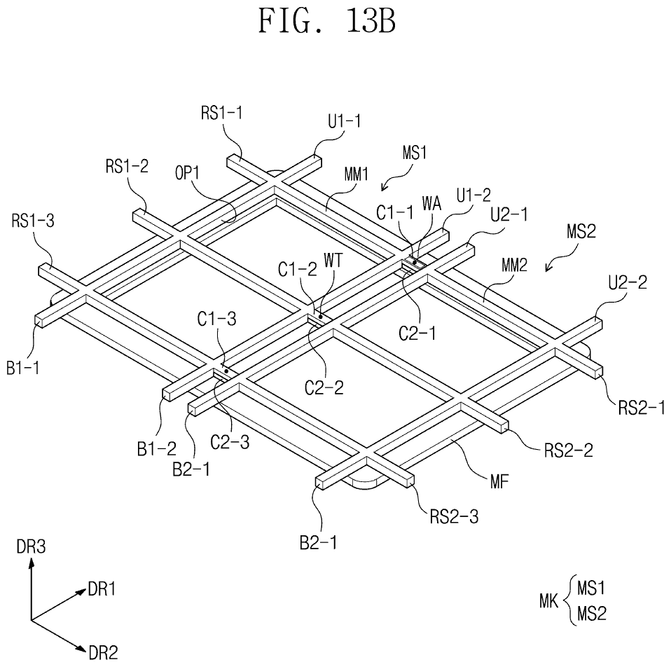

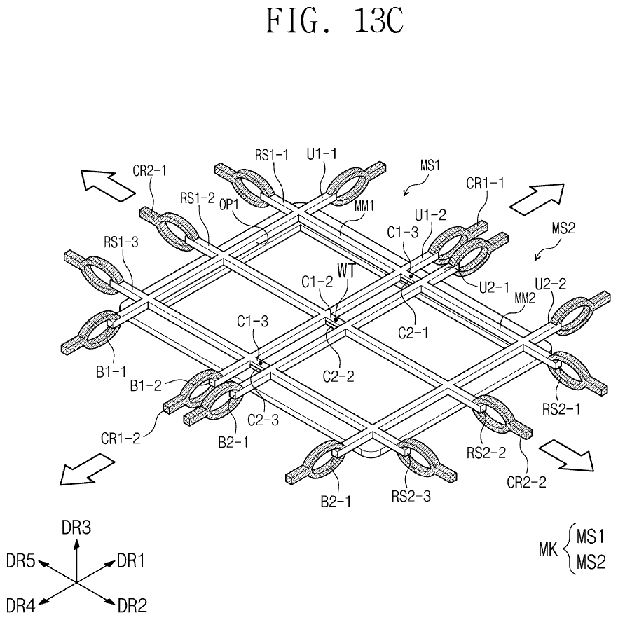

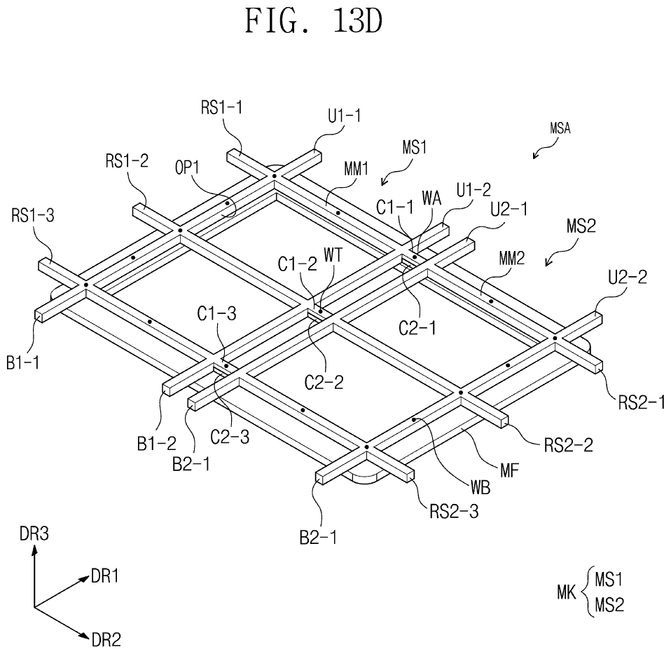

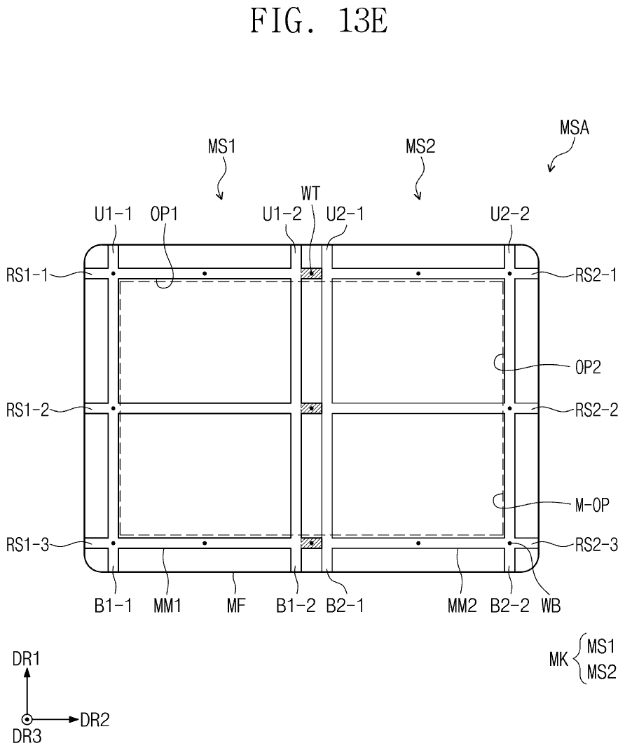

FIGS. 13A to 13D are schematic perspective views illustrating a mask assembly manufacturing method according to an embodiment. FIG. 13E is a schematic plan view illustrating a mask assembly manufacturing method according to an embodiment. Same/similar reference numbers or symbols refer to the same/similar elements as/to those described with reference to FIGS. 1 to 5 and duplicate description is omitted. A method for manufacturing the mask assembly MSA described with reference to FIGS. 1 to 5 will be described with reference to FIGS. 13A to 13E.

Referring to FIG. 13A, the method may include disposing a first mask MS1 on a frame MF.

A frame opening M-OP may be defined in the frame MF. The first mask MS1 may include a first body part MM1, in which first openings OP1 are defined, first tension portions U1-1, U1-2, B1-1, B1-2, RS1-1, RS1-2 and RS1-3, and first coupling portions C1-1, C1-2 and C1-3. The first openings OP1 and the first tension portions U1-1, U1-2, B1-1, B1-2, RS1-1, RS1-2 and RS1-3 may be formed by etching a mother substrate including invar and/or stainless steel. The first coupling portions C1-1, C1-2 and C1-3 may be formed by half-etching the mother substrate.

Thereafter, the method may include disposing a second mask MS2 on the frame MF. The second mask MS2 may include a second body part MM2, in which second openings OP2 are defined, second tension portions U2-1, U2-2, B2-1, B2-2, RS2-1, RS2-2 and RS2-3, and second coupling portions C2-1, C2-2 and C2-3. The second openings OP2 and the second tension portions U2-1, U2-2, B2-1, B2-2, RS2-1, RS2-2 and RS2-3 may be formed by etching a mother substrate including invar and/or stainless steel. The second coupling portions C2-1, C2-2 and C2-3 may be formed by half-etching the mother substrate.

Referring to FIG. 13B, the method may include aligning the first coupling portions C1-1, C1-2 and C1-3 with the second coupling portions C2-1, C2-2 and C2-3 corresponding thereto. The first coupling portions C1-1, C1-2 and C1-3 and the second coupling portions C2-1, C2-2 and C2-3 may correspond to each other and overlap each other in a plan view.

The method may include coupling the aligned first coupling portions C1-1, C1-2 and C1-3 and second coupling portions C2-1, C2-2 and C2-3 to each other to form a mask sheet MK. The first coupling portions C1-1, C1-2 and C1-3 and the second coupling portions C2-1, C2-2 and C2-3 may correspond one-to-one to each other to define coupling regions WA. The first coupling portions C1-1, C1-2 and C1-3 and the second coupling portions C2-1, C2-2 and C2-3 may be coupled to each other by welding in the coupling regions WA. A coupling welding protrusion WA may be formed in each of the coupling regions WT. The first and second masks MS1 and MS2 may be formed as one mask sheet MK by welding.

Thereafter, referring to FIG. 13C, the method may include tensioning the tension portions U1-1, U1-2, B1-1, B1-2, RS1-1, RS1-2, RS1-3, U2-1, U2-2, B2-1, B2-2, RS2-1, RS2-2 and RS2-3 of the mask sheet MK. The tension portions U1-1, U1-2, B1-1, B1-2, RS1-1, RS1-2, RS1-3, U2-1, U2-2, B2-1, B2-2, RS2-1, RS2-2 and RS2-3 may be coupled to corresponding clamps CR1-1, CR1-2, CR2-1 and CR2-2.

The tension portions U1-1, U1-2, U2-1 and U2-2 protruding from the corresponding body part MM1 or MM2 in the first direction DR1 may be tensioned by the first-1 clamps CR1-1 in the first direction DR1. The tension portions B1-1, B1-2, B2-1 and B2-2 protruding from the corresponding body part MM1 or MM2 in a fourth direction DR4 may be tensioned by the first-2 clamps CR1-2 in the fourth direction DR4. The tension portions RS1-1, RS1-2 and RS1-3 protruding from the corresponding body part MM1 or MM2 in a fifth direction DR5 may be tensioned by the second-1 clamps CR2-1 in the fifth direction DR5. The tension portions RS2-1, RS2-2 and RS2-3 protruding from the corresponding body part MM1 or MM2 in the second direction DR2 may be tensioned by the second-2 clamps CR2-2 in the second direction DR2.

Thereafter, referring to FIG. 13D, the method may further include coupling the mask sheet MK in the tensioned state to the frame MF. The clamps CR1-1, CR1-2, CR2-1 and CR2-2 are omitted in FIG. 13D. In the tensioned state, the mask sheet MK may be coupled to the frame MF by welding. Accordingly, frame welding protrusions WB may be formed in a region of the mask sheet MK, which overlaps the frame MF.

Referring to FIG. 13E, the method may further include removing at least a portion of each of the tension portions U1-1, U1-2, B1-1, B1-2, RS1-1, RS1-2, RS1-3, U2-1, U2-2, B2-1, B2-2, RS2-1, RS2-2 and RS2-3 of the mask sheet MK. FIG. 13E illustrates that a portion of each of the tension portions U1-1, U1-2, B1-1, B1-2, RS1-1, RS1-2, RS1-3, U2-1, U2-2, B2-1, B2-2, RS2-1, RS2-2 and RS2-3 remains on the frame MF after the removing the tension portions. However, the disclosure is not limited thereto, and after the removing the tension portions, all of the tension portions U1-1, U1-2, B1-1, B1-2, RS1-1, RS1-2, RS1-3, U2-1, U2-2, B2-1, B2-2, RS2-1, RS2-2 and RS2-3 may be removed from the corresponding body part MM1 or MM2 as described with respect to FIG. 3B.

A mask assembly MSA illustrated in FIG. 13E may be used to form the functional layers included in the display panel DP described with reference to FIG. 6. The functional layers may be defined as a common layer.

A mask assembly MSA according to an embodiment may form one mask sheet. Accordingly, even in case that the display panel DP has the large area, the number of the masks may increase to correspond to the large area so as to easily adjust the size of the mask sheet.

As the mask assembly may have the structure in which the one mask sheet is tensioned in four directions and coupled to the frame, the sagging by the weight of the mask sheet itself may be prevented. As the multiple tension portions may not overlap the opening, the shapes of the openings may be prevented from changing during the tensioning of the mask sheet. Accordingly, a mask assembly with improved manufacture precision and a method for manufacturing the same may be provided.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A mask assembly, comprising
a frame extending in a first direction and a second direction intersecting each other, the frame including a frame opening; and
a mask sheet coupled to the frame, the mask sheet including:
a first mask that includes:
a first body part having:
at least one first deposition opening corresponding to the frame opening;
first tension portions protruding from sides of the first body part; and
a first coupling portion extending from another side of the first body part; and
a second mask that includes:
a second body part having:
at least one second deposition opening corresponding to the frame opening;
second tension portions protruding from sides of the second body part; and
a second coupling portion extending from another side of the second body part,
wherein a bottom surface of the first coupling portion and an upper surface of the second coupling portion contact each other.

2. The mask assembly of claim 1, wherein
the first tension portions include a first upper tension portion and a first lower tension portion adjacent to the second mask and spaced apart in the first direction with the first body part disposed between the first upper tension portion and the first lower tension portion of the first tension portions,
the first coupling portion protrudes from the first upper tension portion, the first body part, and the first lower tension portion in the second direction, and
the second tension portions include a first upper tension portion and a second lower tension portion adjacent to the second mask and spaced apart from the first body part with the first body part disposed between the first upper tension portion and the second lower tension portion of the second tension portions,
the first coupling portion protrudes from the first upper tension portion, the first body part, and the first lower tension portion in the second direction,
the second tension portions include a second upper tension portion and a second lower tension portion adjacent to the first mask and spaced apart in the first direction with the second body part disposed between the second upper tension portion and the second lower tension portion, and
the second coupling portion protrudes from the second upper tension portion, the second body part, and the second lower tension portion in the second direction.

3. The mask assembly of claim 2, wherein
a width of the first lower tension portion, the first body part, and the first upper tension portion is equal to a width of the first coupling portion in the first direction, and
a width of the second lower tension portion, the second body part, and the second upper tension portion is equal to a width of the second coupling portion in the first direction.

4. The mask assembly of claim 2, wherein
a thickness of the first coupling portion is thinner than a thickness of the first lower tension portion, the first body part, and the upper tension portion, and
a thickness of the second coupling portion is thinner than a thickness of the second lower tension portion, the second body part, and the second upper tension portion.

5. The mask assembly of claim 1, wherein a sum of a thicknesses of the first coupling portion and the second coupling portion that overlap each other is equal to a thickness of the first body part or a thickness of the second body part.

6. The mask assembly of claim 1, wherein a coupling region overlapping the first coupling portion and the second coupling portion which overlap each other, has a width of about 500 μm to about 5 mm in the first direction.

7. The mask assembly of claim 1, wherein the frame, the first mask, and the second mask each comprise at least one of invar and stainless steel.

8. The mask assembly of claim 1, wherein
the at least one first deposition opening and at least one second deposition opening are provided in each of n rows×m columns, and
the at least one first deposition opening and at least one second deposition opening are disposed apart from each other in the first direction and the second direction, n and m being natural numbers.

9. The mask assembly of claim 1, wherein
the at least one first deposition opening includes a plurality of first deposition openings,
the at least one second deposition opening includes a plurality of second deposition openings, and
the plurality of first deposition openings are disposed in a different shape from the plurality of second deposition openings.

10. The mask assembly of claim 1, wherein each of the first coupling portion and the second coupling portion has a rectangular shape extending in the first direction.
